(19) United States
(12) Patent Application Publication
(10) Pub. No.: US 2019/0173014 A1
(43) Pub. Date: Jun. 6, 2019

(54) BENZODIAZABOROLE DERIVATIVES AND ORGANIC LIGHT-EMITTING DIODES USING THE SAME

(71) Applicant: YUAN ZE UNIVERSITY, Chung-Li (TW)

(72) Inventors: Hio-Tong IEONG, Chung-Li (TW); Chi-Feng LIN, Chung-Li (TW); Man-Kit LEUNG, Chung-Li (TW); Jiun-Haw LEE, Chung-Li (TW); Tien-Lung CHIU, Chung-Li (TW); Li-Jen HUANG, Chung-Li (TW); Sheng-Chieh LIN, Chung-Li (TW)

(21) Appl. No.: 16/193,600

(22) Filed: Nov. 16, 2018

(30) Foreign Application Priority Data
Dec. 1, 2017 (TW) 106142208

(51) Int. Cl. H01L 51/00; C07F 5/02; C09K 11/06

(52) U.S. Cl. CPC H01L 51/008; H01L 51/5016; C09K 11/06; C07F 5/027

(57) ABSTRACT

A benzodiazaborole derivative is shown in General Formula (1),

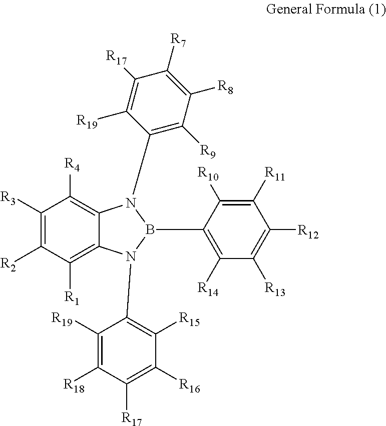

wherein R₁ is selected from the group consisting of hydrogen atom, General Formula (2), General Formula (3) and General Formula (4), R₂ is selected from the group consisting of hydrogen atom, General Formula (3) and General Formula (4), R₁ and R₂ are different and at least one of them is a hydrogen atom, R₃ is General Formula (4) when R₂ is General Formula (4) and R₃ is a hydrogen atom when R₂ is a hydrogen atom or General Formula (3).

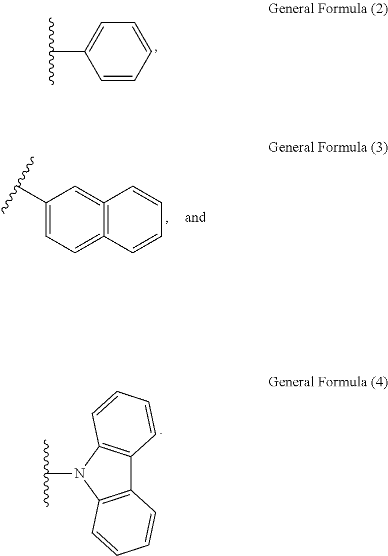

Wherein R₄ to R₁₉ are independently selected from the group consisting of hydrogen atom, fluorine atom, cyano group, alkyl group, cycloalkyl group, alkoxy group, haloalkyl group, thioalkyl group, silyl group and alkenyl group.

### CROSS REFERENCE TO RELATED APPLICATIONS

This Non-provisional application claims priority under 35 U.S.C. § 119(a) on Patent Application No(s). 106142208 filed in Taiwan, Republic of China on Dec. 1, 2017, the entire contents of which are hereby incorporated by reference.

### BACKGROUND

### Technology Field

The present disclosure relates to electroluminescent materials and light-emitting elements by using the same and, in particular, to benzodiazaborole derivatives and organic light-emitting diodes by using the same.

### Description of Related Art

With the advances in electronic technology, a light weight and high efficiency flat display device has been developed. An organic electroluminescent device possibly becomes the mainstream of the next generation flat panel display device due to its advantages of self-luminosity, no restriction on viewing angle, power conservation, simple manufacturing process, low cost, high response speed, full color and so on.

In general, the organic electroluminescent device includes an anode, an organic luminescent layer and a cathode. When applying a direct current to the organic electroluminescent device, electron holes and electrons are injected into the organic luminescent layer from the anode and the cathode, respectively. Charge carriers move and then recombine in the organic luminescent layer because of the potential difference caused by an applied electric field. The excitons generated by the recombination of the electrons and the electron holes may excite the luminescent molecules in the organic luminescent layer. The excited luminescent molecules then release the energy in the form of light.

Nowadays, the organic electroluminescent device usually adopts a host-guest emitter system. The organic luminescent layer disposed therein includes a host material and a guest material. The electron holes and the electrons are mainly transmitted to the host material to perform recombination and thereby generate energy, and then the energy is transferred to the guest material to generate light. The guest material can be categorized into fluorescent material and phosphorescent material. Theoretically, the internal quantum efficiency can approach 100% by using appropriate phosphorescent materials. Therefore, the phosphorescent materials recently have become one of the most important developments in the field of organic electroluminescent materials.

In the development of blue host materials, the triplet energy level of the host materials must be higher than or equal to that of the guest materials to avoid the energy lost caused by reverse energy transfer. The energy lost can result in low luminous efficiency (i.e., low current efficiency) and short lifespan, etc. Therefore, it is necessary for the host materials to have a greater triplet energy level.

Besides, the selection of organic electroluminescent material is not only based on the matching energy level but also the high temperature of decomposition. These properties can avoid pyrolysis and the decrease of stability.

Accordingly, the present disclosure provides benzodiazaborole derivatives and organic light-emitting diodes by using the same which have good optical efficiency and thermal stability.

### SUMMARY

In view of the foregoing, an objective of the present disclosure is to provide benzodiazaborole derivatives and organic light-emitting diodes by using the same which have good optical efficiency and thermal stability.

To achieve the above objective, the present disclosure provides a benzodiazaborole derivative, comprising a structure of the following General Formula (1).

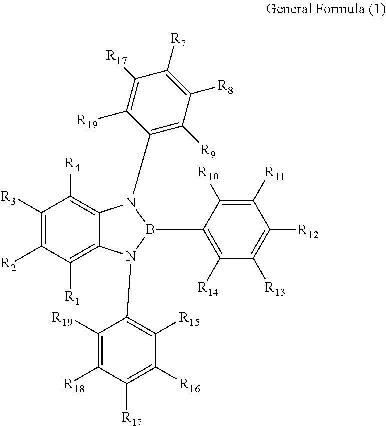

Wherein, R₁ is selected from the group consisting of hydrogen atom, General Formula (2), General Formula (3) and General Formula (4), R₂ is selected from the group consisting of hydrogen atom, General Formula (3) and General Formula (4), R₁ and R₂ are different and at least one of them is a hydrogen atom, R₃ is General Formula (4) when R₂ is General Formula (4), and R₃ is a hydrogen atom when R₂ is a hydrogen atom or General Formula (3).

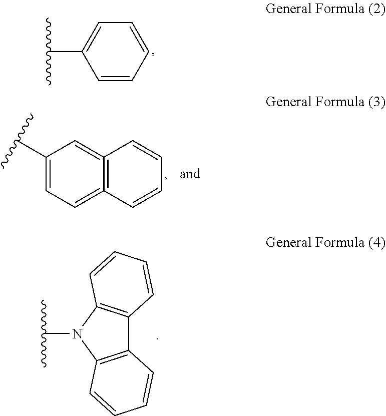

Wherein, R₄ to R₁₉ are independently selected from the group consisting of hydrogen atom, fluorine atom, cyano group, alkyl group, cycloalkyl group, alkoxy group, haloalkyl group, thioalkyl group, silyl group and alkenyl group.

In one embodiment, the alkyl group is selected from the group consisting of a substituted or unsubstituted straight-chain C1˜C6 alkyl group, and a substituted or unsubstituted branched-chain C3˜C6 alkyl group, the cycloalkyl group is a substituted or unsubstituted C3˜C6 cycloalkyl group, the alkoxy group is selected from the group consisting of a substituted or unsubstituted straight-chain C1˜C6 alkoxy group, and a substituted or unsubstituted branched-chain C3˜C6 alkoxy group, the haloalkyl group is selected from the group consisting of a substituted or unsubstituted straight-chain C1˜C6 haloalkyl group, and a substituted or unsubstituted branched-chain C3˜C6 haloalkyl group, the thioalkyl group is selected from the group consisting of a substituted or unsubstituted straight-chain C1˜C6 thioalkyl group, and a substituted or unsubstituted branched-chain C3˜C6 thioalkyl group, the silyl group is selected from the group consisting of a substituted or unsubstituted straight-chain C1˜C6 silyl group, and a substituted or unsubstituted branched-chain C3˜C6 silyl group, the alkenyl group is selected from the group consisting of a substituted or unsubstituted straight-chain C2˜C6 alkenyl group, and a substituted or unsubstituted branched-chain C3˜C6 alkenyl group.

In one embodiment, the benzodiazaborole derivative comprises a structure of any of the following Chemical Formulas (1) to (5):

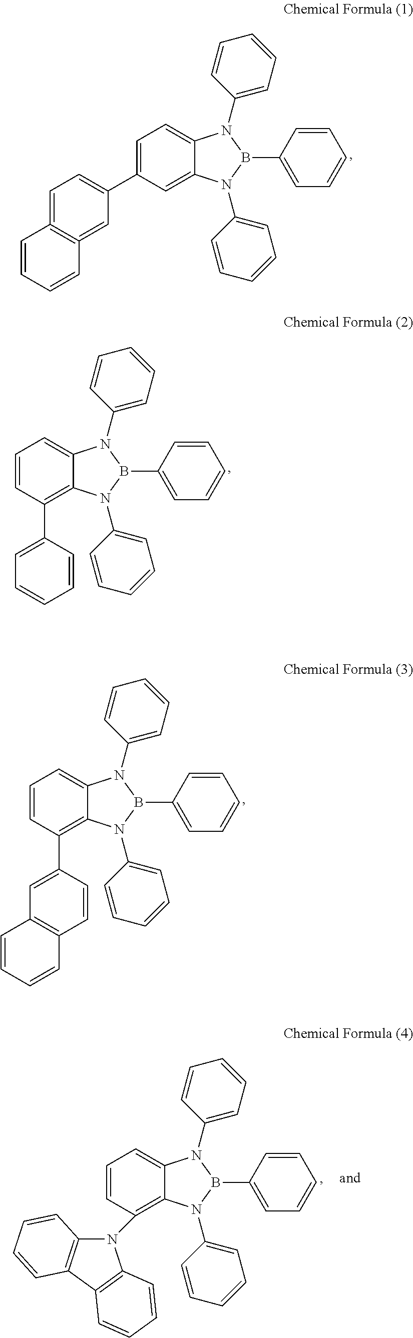

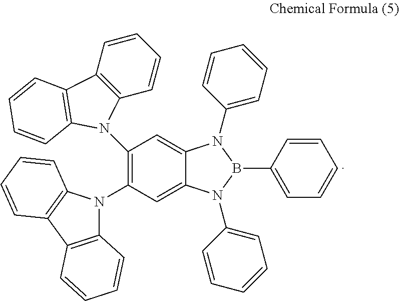 [SMILES: c1ccc(B2N(c3ccccc3)c3cc(-n4c5ccccc5c5ccccc54)c(-n4c5ccccc5c5ccccc54)cc3N2c2ccccc2)cc1]

To achieve the above objective, the present disclosure also provides an organic light-emitting diode, which comprises a first electrode layer, a second electrode layer, and an organic luminescent unit disposed between the first electrode layer and the second electrode layer. The organic luminescent unit comprises at least a benzodiazaborole derivative, and the benzodiazaborole derivative comprises a structure of the following General Formula (1):

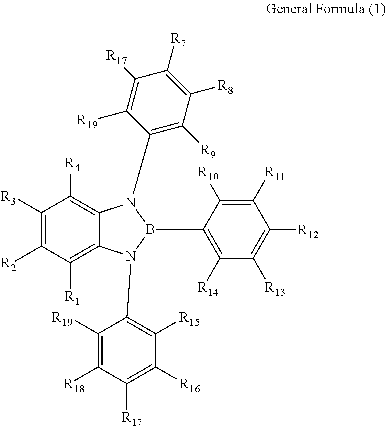

Wherein, R₁ is selected from the group consisting of hydrogen atom, General Formula (2), General Formula (3) and General Formula (4), R₂ is selected from the group consisting of hydrogen atom, General Formula (3) and General Formula (4), R₁ and R₂ are different and at least one of them is a hydrogen atom, R₃ is General Formula (4) when R₂ is General Formula (4), and R₃ is a hydrogen atom when R₂ is a hydrogen atom or General Formula (3).

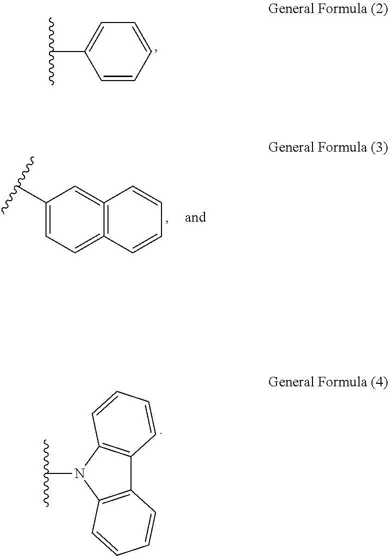

Wherein, R₄ to R₁₉ are independently selected from the group consisting of hydrogen atom, fluorine atom, cyano group, alkyl group, cycloalkyl group, alkoxy group, haloalkyl group, thioalkyl group, silyl group and alkenyl group.

In one embodiment, the alkyl group is selected from the group consisting of a substituted or unsubstituted straight-chain C1˜C6 alkyl group, and a substituted or unsubstituted branched-chain C3˜C6 alkyl group, the cycloalkyl group is a substituted or unsubstituted C3˜C6 cycloalkyl group, the alkoxy group is selected from the group consisting of a substituted or unsubstituted straight-chain C1˜C6 alkoxy group, and a substituted or unsubstituted branched-chain C3˜C6 alkoxy group, the haloalkyl group is selected from the group consisting of a substituted or unsubstituted straight-chain C1˜C6 haloalkyl group, and a substituted or unsubstituted branched-chain C3˜C6 haloalkyl group, the thioalkyl group is selected from the group consisting of a substituted or unsubstituted straight-chain C1˜C6 thioalkyl group, and a substituted or unsubstituted branched-chain C3˜C6 thioalkyl group, the silyl group is selected from the group consisting of a substituted or unsubstituted straight-chain C1˜C6 silyl group, and a substituted or unsubstituted branched-chain C3˜C6 silyl group, the alkenyl group is selected from the group consisting of a substituted or unsubstituted straight-chain C2˜C6 alkenyl group, and a substituted or unsubstituted branched-chain C3˜C6 alkenyl group.

In one embodiment, the benzodiazaborole derivative comprises a structure of any of the following Chemical Formulas (1) to (5):

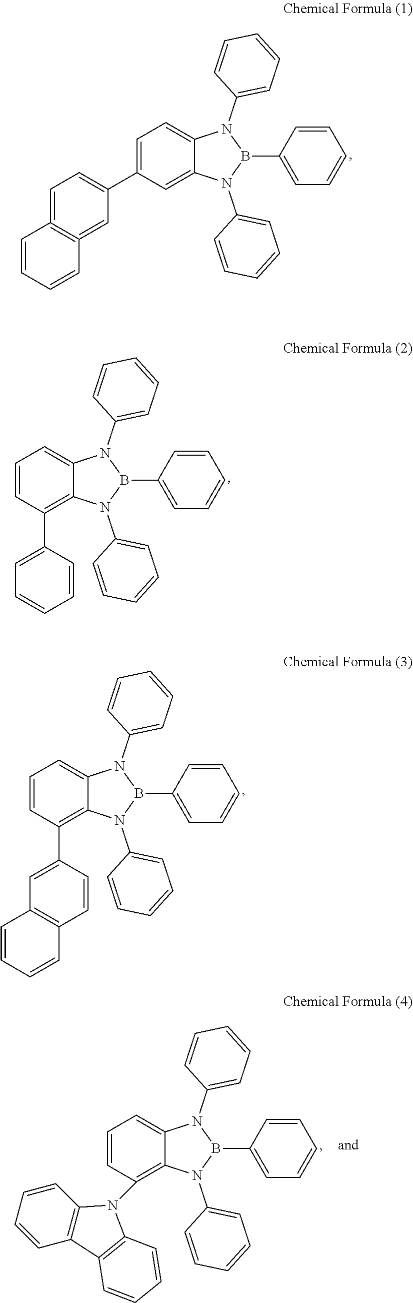

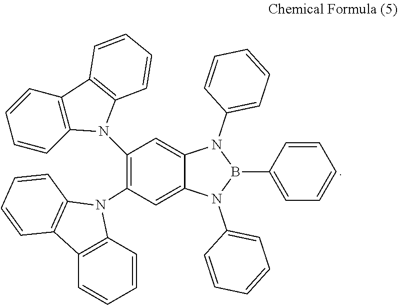 [SMILES: c1ccc(B2N(c3ccccc3)c3cc(-n4c5ccccc5c5ccccc54)c(-n4c5ccccc5c5ccccc54)cc3N2c2ccccc2)cc1]

In one embodiment, the organic luminescent unit comprises an organic luminescent layer.

In one embodiment, the organic luminescent unit further comprises a hole transport layer and an electron transport layer, and the organic luminescent layer is disposed between the hole transport layer and the electron transport layer.

In one embodiment, the organic luminescent unit further comprises a hole transport layer, an electron blocking layer, an electron transport layer and an electron injection layer, and the electron blocking layer, the organic luminescent layer and the electron transport layer are sequentially disposed between the hole transport layer and the electron injection layer.

In one embodiment, the organic luminescent layer comprises the benzodiazaborole derivative.

In one embodiment, the organic luminescent unit further comprises an electron blocking layer, and the electron blocking layer comprises the benzodiazaborole derivative.

As mentioned above, in the benzodiazaborole derivatives and the organic light-emitting diodes by using the same according to the present disclosure, it utilizes 1,3,2-benzodiazaborole as a core structure. Because of the 10 π electrons of the 1,3,2-benzodiazaborole and an empty p_{z} orbital of the boron atom, it shows unique photoelectric properties and high triplet energy levels. Different substituents are introduced to the ortho and/or meta positions of the benzo group to improve its thermal stability and adjust its electrochemical properties. In addition, the 1,3,2-benzodiazaborole derivatives of the present disclosure can be used as the material of the electron blocking layer and the organic luminescent layer. Besides, as the 1,3,2-benzodiazaborole derivatives of the present disclosure have good optical efficiency and thermal stability, they are suitable for the blue phosphorescent organic light-emitting diodes.

### BRIEF DESCRIPTION OF THE DRAWINGS

The disclosure will become more fully understood from the detailed description and accompanying drawings, which are given for illustration only, and thus are not limitative of the present disclosure, and wherein:

FIG. 1 is a sectional view of an organic light-emitting diode according to a second embodiment of this disclosure;

FIG. 2 is a sectional view of an organic light-emitting diode according to a third embodiment of this disclosure;

FIG. 3 is a sectional view of an organic light-emitting diode according to a fourth embodiment of this disclosure;

FIG. 4 is a schematic graph showing the charge injection properties of the hole-only device (HOD) with the organic layer made of mCb or the benzodiazaborole derivative of Chemical Formula (5); and

FIG. 5 is a schematic graph showing the charge injection properties of the electron-only device (EOD) with the organic layer made of mCb or the benzodiazaborole derivative of Chemical Formula (5).

### DETAILED DESCRIPTION OF THE DISCLOSURE

The present disclosure will be apparent from the following detailed description, which proceeds with reference to the accompanying drawings, wherein the same references relate to the same elements.

Benzodiazaborole Derivatives

A first embodiment of the present disclosure provides a benzodiazaborole derivative, comprising a structure of the following General Formula (1),

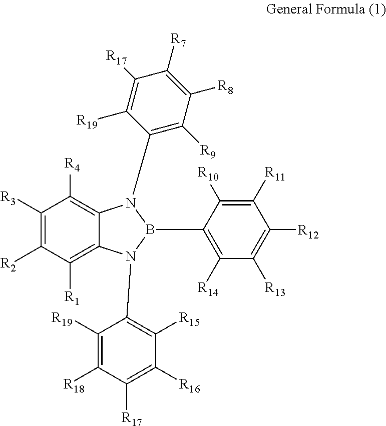

Wherein, R₁ is selected from the group consisting of hydrogen atom, General Formula (2), General Formula (3) and General Formula (4), R₂ is selected from the group consisting of hydrogen atom, General Formula (3) and General Formula (4), R₁ and R₂ are different and at least one of them is a hydrogen atom, R₃ is General Formula (4) when R₂ is General Formula (4), and R₃ is a hydrogen atom when R₂ is a hydrogen atom or General Formula (3).

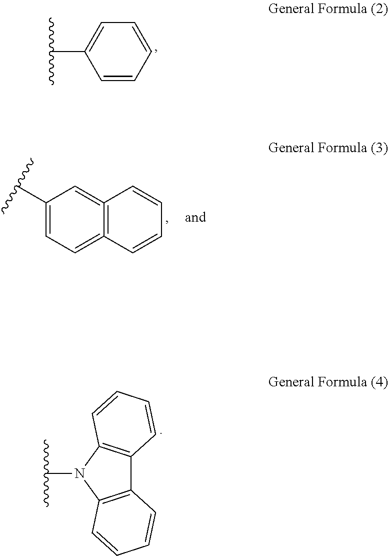

Wherein, R₄ to R₁₉ are independently selected from the group consisting of hydrogen atom, fluorine atom, cyano group, alkyl group, cycloalkyl group, alkoxy group, haloalkyl group, thioalkyl group, silyl group and alkenyl group.

Herein, the alkyl group is selected from the group consisting of a substituted or unsubstituted straight-chain C1˜C6 alkyl group, and a substituted or unsubstituted branched-chain C3˜C6 alkyl group, the cycloalkyl group is a substituted or unsubstituted C3˜C6 cycloalkyl group, the alkoxy group is selected from the group consisting of a substituted or unsubstituted straight-chain C1˜C6 alkoxy group, and a substituted or unsubstituted branched-chain C3˜C6 alkoxy group, the haloalkyl group is selected from the group consisting of a substituted or unsubstituted straight-chain C1˜C6 haloalkyl group, and a substituted or unsubstituted branched-chain C3˜C6 haloalkyl group, the thioalkyl group is selected from the group consisting of a substituted or unsubstituted straight-chain C1˜C6 thioalkyl group, and a substituted or unsubstituted branched-chain C3˜C6 thioalkyl group, the silyl group is selected from the group consisting of a substituted or unsubstituted straight-chain C1˜C6 silyl group, and a substituted or unsubstituted branched-chain C3˜C6 silyl group, the alkenyl group is selected from the group consisting of a substituted or unsubstituted straight-chain C2˜C6 alkenyl group, and a substituted or unsubstituted branched-chain C3˜C6 alkenyl group.

The benzodiazaborole derivative of General Formula (1) according to the embodiment can be a host material of an organic luminescent layer in an organic electroluminescent device. A preferred example is the compound of Chemical Formula (1), mNp, where R₂ is the structure of the General Formula (3), and R₁ and R₃ to R₁₉ are independent hydrogen atoms.

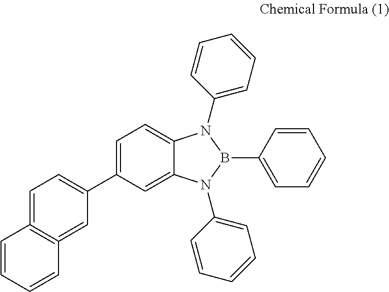

Alternatively, another preferred example is the compound of Chemical Formula (2), oPh, where R₁ is the structure of the General Formula (2), and R₂ to R₁₉ are independent hydrogen atoms.

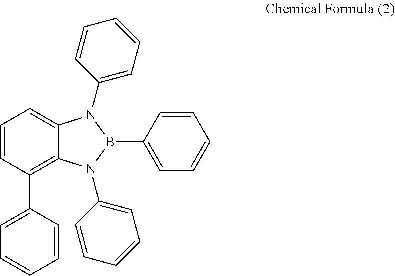

Alternatively, another preferred example is the compound of Chemical Formula (3), oNp, where R₁ is the structure of the General Formula (3), and R₂ to R₁₉ are independent hydrogen atoms.

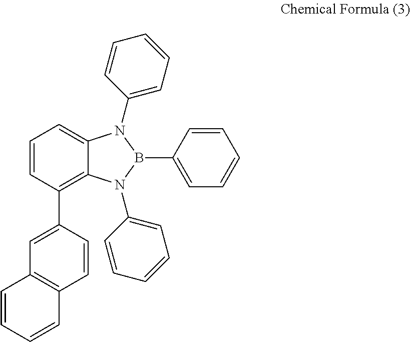

Alternatively, another preferred example is the compound of Chemical Formula (4), oCb, where R₁ is the structure of the General Formula (4), and R₂ to R₁₉ are independent hydrogen atoms.

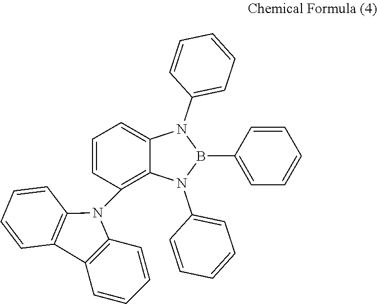

Alternatively, another preferred example is the compound of Chemical Formula (5), dCb, where R₂ and R₃ are the structure of the General Formula (4), and R₁ and R₄ to R₁₉ are independent hydrogen atoms.

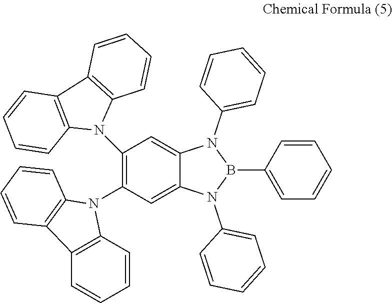

In the Chemical Formulas (1) to (5), 1,3,2-benzodiazaborole is utilized as a core structure, and different substituents are introduced to the ortho and/or meta positions of the benzo group to improve its thermal stability and adjust its electrochemical properties, thereby providing a series of benzodiazaborole derivatives.

Accordingly, the benzodiazaborole derivatives have good electrochemical properties and thermal stability. Moreover, as the 1,3,2-benzodiazaborole has 10 π electrons and an empty p_{z} orbital of the boron atom, it has unique photoelectric properties and high triplet energy levels. Thus, they can be the host materials for the blue phosphorescent organic light-emitting diodes.

In this embodiment, the guest materials for use with the host materials may be any suitable materials applied to the organic luminescent layer of the organic electroluminescent device, for example but not limited to, the following Chemical Formula (6) (Ir(2-phq)₃), Chemical Formula (7) (Ir(ppy)₃), and Chemical Formula (8) (FIrpic).

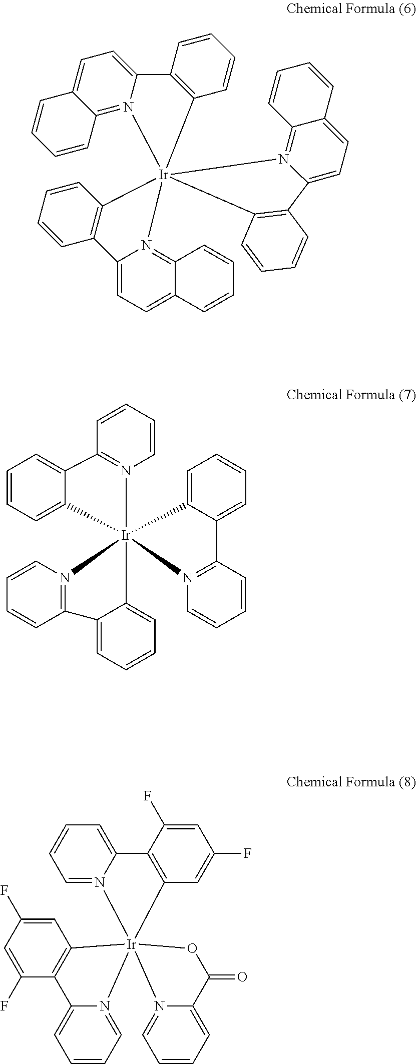

To be noted, the structure of the General Formula (1) of this embodiment can not only be applied to the organic luminescent layer, but also be used in the electron blocking layer of the organic light-emitting unit.

Organic Light-Emitting Diodes

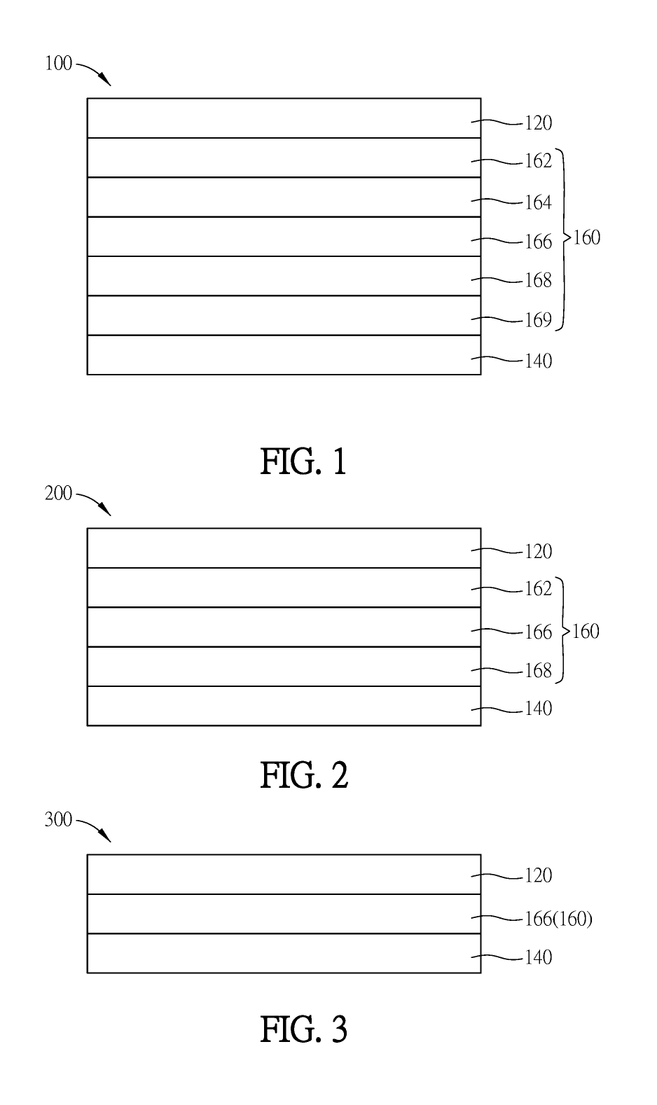

Please refer to FIG. 1, an organic light-emitting diode 100 according to the second embodiment of the disclosure includes a first electrode layer 120, a second electrode layer 140 and an organic luminescent unit 160. In the embodiment, the first electrode layer 120 can be a transparent electrode material, such as indium tin oxide (ITO), and the second electrode layer 140 can be a metal, transparent conductive substance or any other suitable conductive material. On the other hand, the first electrode layer 120 can also be a metal, transparent conductive substance or any other suitable conductive material, and the second electrode layer 140 can also be a transparent electrode material. Overall, at least one of the first electrode layer 120 and the second electrode layer 140 of the embodiment is a transparent electrode material, so that the light emitted from the organic luminescent unit 160 may pass through the transparent electrode, thereby enabling the organic light-emitting diode 100 to emit light.

In addition, please also refer to FIG. 1, the organic luminescent unit 160 can comprise a hole transport layer 162, an electron blocking layer 164, an organic luminescent layer 166, an electron transport layer 168 and an electron injection layer 169. The electron blocking layer 164, the organic luminescent layer 166 and the electron transport layer 168 are sequentially disposed between the hole transport layer 162 and the electron injection layer 169.

Herein, the materials of the hole transport layer 162 may be 1,1-Bis[4-[N,N′-di(p-tolyl)amino]phenyl]cyclohexane (TAPC), N,N-bis-(1-naphthyl)-N,N-diphenyl-1,1-biphenyl-4,4-diamine (NPB) or N-N′-diphenyl-N-Nbis(3-methylphenyl)-[1-1′-biphenyl]-4-4′-diamine (TPD) and so on. Moreover, the thickness of the hole transport layer 162 of the embodiment ranges, for example, from 0 nm to 100 nm. In the embodiment, the hole transport layer 162 can increase the injection rate of electron holes from the first electrode layer 120 to the organic luminescent layer 166 and can also reduce the driving voltage of the organic light-emitting diode 100.

The materials of the electron blocking layer 164 may be N,N′-dicarbazolyl-3,5-benzene (mCP) or any other material with low electron affinity. In the embodiment, the thickness of the electron blocking layer 164 ranges, for example, from 0 nm to 30 nm. The electron blocking layer 164 may further increase the transport rate of the electron hole from the hole transport layer 162 to the organic luminescent layer 166.

In addition, the thickness of the organic luminescent layer 166 of the embodiment is, for example, between 5 nm and 60 nm. For example, the thickness of the organic luminescent layer 166 of the embodiment is 30 nm. The organic luminescent layer 166 includes a host material and a guest material, and the host material can be the above-mentioned benzodiazaborole derivative which has a structure of the following General Formula (1).

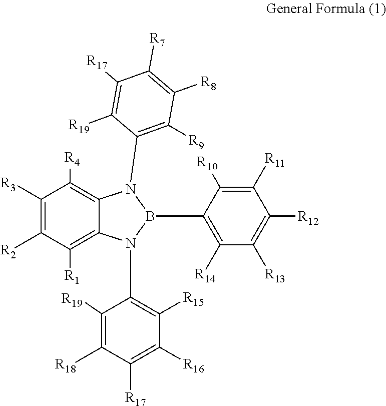

Wherein, R₁ is selected from the group consisting of hydrogen atom, General Formula (2), General Formula (3) and General Formula (4), R₂ is selected from the group consisting of hydrogen atom, General Formula (3) and General Formula (4), R₁ and R₂ are different and at least one of them is a hydrogen atom, R₃ is General Formula (4) when R₂ is General Formula (4), and R₃ is a hydrogen atom when R₂ is a hydrogen atom or General Formula (3).

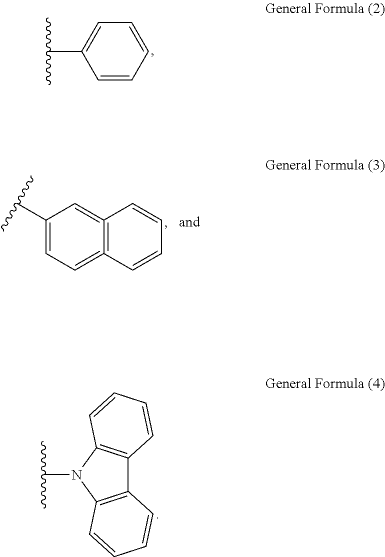

Wherein, R₄ to R₁₉ are independently selected from the group consisting of hydrogen atom, fluorine atom, cyano group, alkyl group, cycloalkyl group, alkoxy group, haloalkyl group, thioalkyl group, silyl group and alkenyl group.

Herein, the alkyl group is selected from the group consisting of a substituted or unsubstituted straight-chain C1˜C6 alkyl group, and a substituted or unsubstituted branched-chain C3˜C6 alkyl group, the cycloalkyl group is a substituted or unsubstituted C3˜C6 cycloalkyl group, the alkoxy group is selected from the group consisting of a substituted or unsubstituted straight-chain C1˜C6 alkoxy group, and a substituted or unsubstituted branched-chain C3˜C6 alkoxy group, the haloalkyl group is selected from the group consisting of a substituted or unsubstituted straight-chain C1˜C6 haloalkyl group, and a substituted or unsubstituted branched-chain C3˜C6 haloalkyl group, the thioalkyl group is selected from the group consisting of a substituted or unsubstituted straight-chain C1˜C6 thioalkyl group, and a substituted or unsubstituted branched-chain C3˜C6 thioalkyl group, the silyl group is selected from the group consisting of a substituted or unsubstituted straight-chain C1˜C6 silyl group, and a substituted or unsubstituted branched-chain C3˜C6 silyl group, the alkenyl group is selected from the group consisting of a substituted or unsubstituted straight-chain C2˜C6 alkenyl group, and a substituted or unsubstituted branched-chain C3˜C6 alkenyl group.

A preferred example is the compound of Chemical Formula (1), mNp, where R₂ is the structure of the General Formula (3), and R₁ and R₃ to R₁₉ are independent hydrogen atoms.

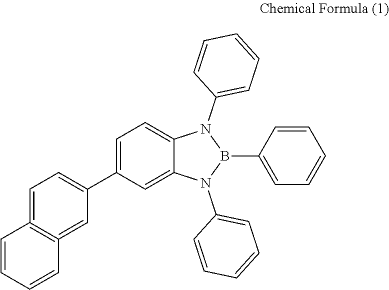

Alternatively, another preferred example is the compound of Chemical Formula (2), oPh, where R₁ is the structure of the General Formula (2), and R₂ to R₁₉ are independent hydrogen atoms.

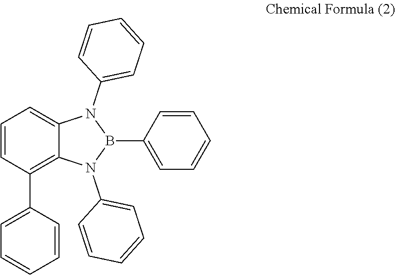

Alternatively, another preferred example is the compound of Chemical Formula (3), oNp, where R₁ is the structure of the General Formula (3), and R₂ to R₁₉ are independent hydrogen atoms.

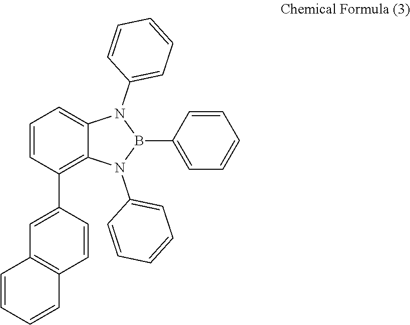

Alternatively, another preferred example is the compound of Chemical Formula (4), oCb, where R₁ is the structure of the General Formula (4), and R₂ to R₁₉ are independent hydrogen atoms.

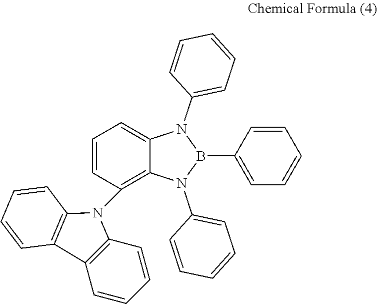

Alternatively, another preferred example is the compound of Chemical Formula (5), dCb, where R₂ and R₃ are the structure of the General Formula (4), and R₁ and R₄ to R₁₉ are independent hydrogen atoms.

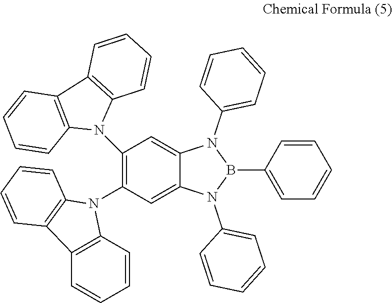

In addition, the guest materials may be any suitable materials applied to the organic luminescent layer of the organic electroluminescent device, for example but not limited to, the following Chemical Formula (6) (Ir(2-phq)₃), Chemical Formula (7) (Ir(ppy)₃), and Chemical Formula (8) (FIrpic).

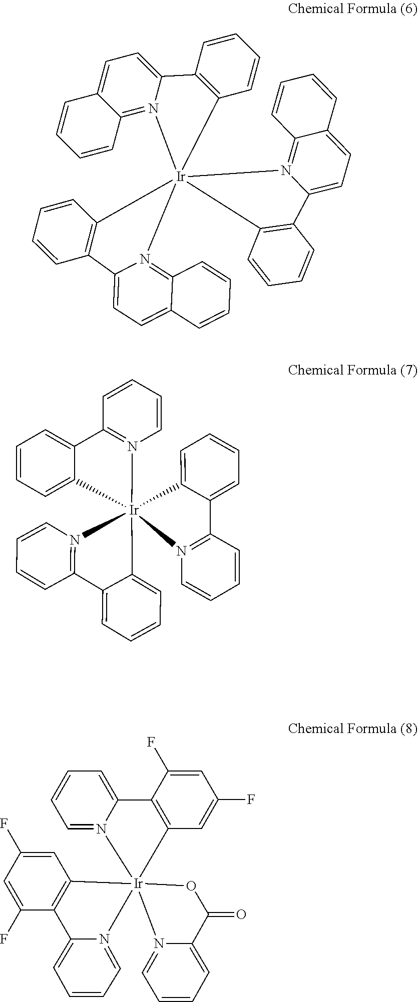

In addition, the material of the electron transport layer 168 may be, but not limited to, a metal complex, such as Tris-(8-hydroxy-quinoline)aluminum (Alq₃), bis(10-hydroxybenzo-[h]quinolinato)beryllium (BeBq₂) and so on, or a heterocyclic compound, such as 2-(4-Biphenylyl)-5-(4-tert-butylphenyl)-1,3,4-oxadiazole (PBD), 3-(4-Biphenyly)-4-phenyl-5-tert-butylphenyl-1,2,4-triazol e (TAZ), 2,2′,2″-(1,3,5-Benzinetriyl)-tris(1-phenyl-1-H-benzimidazol e) (TPBI), diphenylbis(4-(pyridin-3-yl)phenyl)silane (DPPS), 3,3′-[5′-[3-(3-Pyridinyl)phenyl][1,1′:3′,1″-terphenyl]-3,3″-diyl]bispyridine (TmPyPB) and so on. In the embodiment, the thickness of the electron transport layer 168 may be, for example, less than 100 nm. The electron transport layer 168 can facilitate the transfer of electrons from the second electrode layer 140 to the organic luminescent layer 166 to increase the transport rate of the electron. Moreover, the material of the electron injection layer 169 may be, for example, LiF. The thickness of the electron injection layer 169 may be, for example, 0.7 nm.

In addition, FIG. 2 is a sectional view of an organic light-emitting diode 200 according to the third embodiment of the disclosure. The configuration of the organic light-emitting diode 200 is substantially similar with that of the organic light-emitting diode 100, and same elements have substantial the same characteristics and functions. Therefore, the similar references relate to the similar elements, and detailed explanation is omitted hereinafter.

Please refer to FIG. 2, in the embodiment, the organic luminescent unit 160 can comprise a hole transport layer 162, an organic luminescent layer 166 and an electron transport layer 168. The organic luminescent layer 166 is disposed between the hole transport layer 162 and the electron transport layer 168.

In addition, FIG. 3 is a sectional view of an organic light-emitting diode 300 according to the fourth embodiment of the disclosure. The configuration of the organic light-emitting diode 300 is substantially similar with that of the organic light-emitting diode 100, and same elements have substantial the same characteristics and functions. Therefore, the similar references relate to the similar elements, and detailed explanation is omitted hereinafter.

Please refer to FIG. 3, in the embodiment, the organic luminescent unit 160 can comprise an organic luminescent layer 166.

The configuration of the organic light-emitting diode according to the disclosure is not limited to what is disclosed in the second, third or fourth embodiment. The second, third and fourth embodiments are for illustrations only.

In the above-mentioned second, third and fourth embodiments, the materials having the structures of General Formula (1), in addition to being applied to the organic luminescent layer, can also be applied to the electron blocking layer of an organic electroluminescent unit.

To illustrate the synthesis of Chemical Formula (1) to Chemical Formula (5), there are several examples shown below.

### EXAMPLE 1

### Synthesis of Compound 1

1,2-dibromobenzene (1.50 g, 6.40 mmol), palladium acetate (Pd(OAc)₂, 0.04 g, 0.178 mmol), tri-tert-butylphosphonium tetrafluoroborate (0.15 g, 0.52 mmol), and sodium tert-butoxide (NaO^{t}Bu, 1.82 g, 18.95 mmol) were provided in a 50 ml two-neck bottle in an inert atmosphere. The dehydrated and deoxygenated toluene (20 ml) and aniline (1.70 ml, 18.65 mmol) were added into the bottle. The mixture was subjected to reaction in refluxing for 18 hours. After cooling to the room temperature, the solution was filtered by diatomaceous earth. The filtrate was collected and extracted with aqueous ammonium chloride solution. The organic layer was dried with anhydrous MgSO₄ and concentrated under vacuum. The crude was purified through by column chromatography with n-hexane/DCM=4/1 as eluent to obtain compound 1 (1.45 g, yield: 87%) as a white solid. The foregoing reaction is shown in the Reaction Formula (1).

Spectral data as follow: ¹H NMR (400 MHz, DMSO-d₆): δ 7.28-7.23(m, 4H), 7.17(t, J=8.4Hz, 4H), 6.96-6.89(m, 6H), 6.75(t, J=7.3 Hz, 2H); ¹³C NMR (100 MHz, DMSO-d₆): δ 144.47, 134.51, 128.94, 121.96, 119.88, 118.98, 116.16.

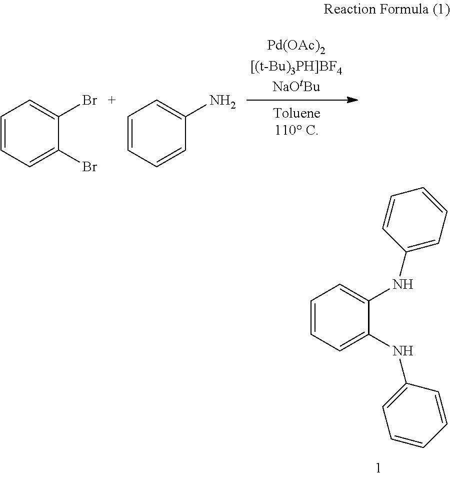

### EXAMPLE 2

### Synthesis of Compound 2

1-bromo-2,3-dichlorobenzene (1.00 g, 4.43 mmol), phenylboronic acid (0.56 g, 4.60 mmol), potassium carbonate (K₂CO₃, 1.38 g, 10.00 mmol), and palladium(II) chloride (PdCl₂, 4.00 mg, 0.02 mmol) were provided in a 100 ml single-neck bottle. After adding with 5 ml ethanol and 15 ml deionized water, the solution was stirred for a half hour at room temperature. The solution was then extracted with DCM/potassium carbonate aqueous solution. The organic layer was dried with anhydrous MgSO₄ and concentrated under vacuum. The crude was purified through by column chromatography with n-hexane as eluent to obtain compound 2 (0.80 g, yield: 82%) as a transparent liquid. The foregoing reaction is shown in the Reaction Formula (2).

Spectral data as follow: ¹H NMR (400 MHz, CDCl₃): δ 7.50-7.39(m, 6H), 7.31-7.25(m, 2H); ¹³C NMR (100 MHz, CDCl₃): δ 142.86, 138.29, 133.57, 131.14, 129.47, 129.41, 129.25, 128.12, 127.92, 127.11; HRMS(FAB) m/z calcd for C₁₂H₈Cl₂ (M⁺) 222.0003, obsd. 222.0003.

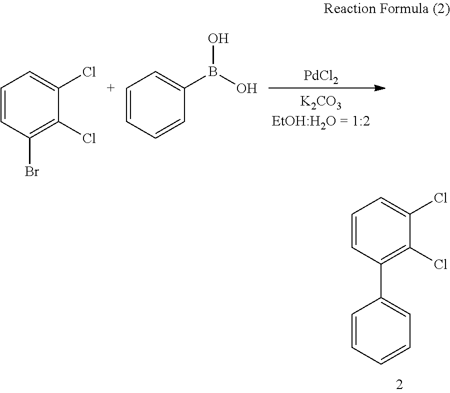

### EXAMPLE 3

### Synthesis of Compound 3

Compound 2 (0.75 g, 3.38 mmol), Bis(dibenzylideneacetone)palladium(0) (Pd(dba)₂, 0.19 g, 0.33 mmol), tri-tert-butylphosphonium tetrafluoroborate (0.19 g, 0.66 mmol), and sodium tert-butoxide (NaO^{t}Bu, 0.95 g, 0.99 mmol) were provided in a 25 ml two-neck bottle in an inert atmosphere. The dehydrated and deoxygenated toluene (16 ml) and aniline (0.90 ml, 9.87 mmol) were added into the bottle. The mixture was heated to 110° C. for 18 hours. After cooling to the room temperature, the solution was filtered by diatomaceous earth. The filtrate was collected and extracted with aqueous ammonium chloride solution. The organic layer was dried with anhydrous MgSO₄ and concentrated under vacuum. The crude was purified through by column chromatography with n-hexane/DCM=4/1 as eluent to obtain compound 3 (0.83 g, yield: 73%) as a white solid. The foregoing reaction is shown in the Reaction Formula (3).

Spectral data as follow: ¹H NMR (400 MHz, DMSO-d₆): δ 7.35-7.18(m, 9H), 7.09-7.07(m, 4H), 7.95(t, J=7.4 Hz, 2H), 6.88-6.83(m, 2H), 6.50(t, J=7.2 Hz, 1H),6.44(d, J=7.6 Hz, 2H); ¹³C NMR (100 MHz, DMSO-d₆): δ 146.66, 143.03, 141.09, 140.93, 129.08, 128.58, 128.53, 127.86, 127.32, 126.76, 126.12, 122.15, 120.39, 118.05, 116.97, 115.22, 113.15; HRMS(FAB) m/z calcd for C₂₄H₂₀N₂ (M⁺) 336.1626, obsd. 336.1623.

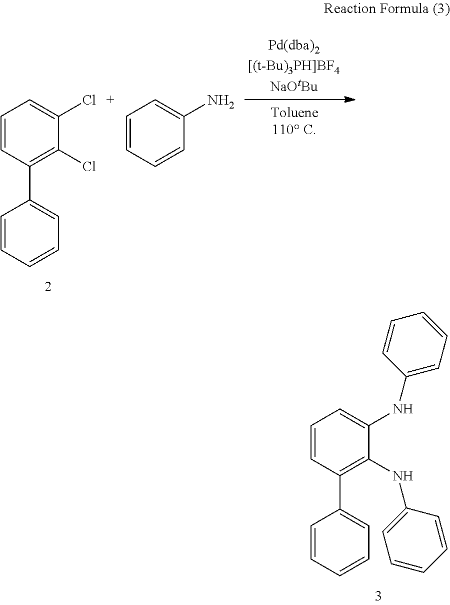

### EXAMPLE 4

### Synthesis of Compound 4

1-bromo-3,4-dichlorobenzene (1.00 g, 4.43 mmol), phenylboronic acid (0.56 g, 4.60 mmol), potassium carbonate (K₂CO₃, 1.38 g, 10.00 mmol), and palladium(II) chloride (PdCl₂, 4.02 mg, 0.02 mmol) were provided in a 100 ml single-neck bottle. After adding with 5 ml ethanol and 15 ml deionized water, the solution was stirred for a half hour at room temperature. The solution was then extracted with DCM/potassium carbonate aqueous solution. The organic layer was dried with anhydrous MgSO₄ and concentrated under vacuum. The crude was purified through by column chromatography with n-hexane as eluent to obtain compound 4 (0.82 g, yield: 84%) as a transparent liquid. The foregoing reaction is shown in the Reaction Formula (4).

Spectral data as follow: ¹H NMR (400 MHz, CDCl₃): δ 7.66(d, J=2.1 Hz, 1H), 7.53-7.34(m, 7H), ¹³C NMR (100 MHz, CDCl₃): δ 141.23, 138.76, 132.81, 131.41, 130.66, 128.99, 128.96, 128.11, 126.94, 126.35; HRMS(FAB) m/z calcd for C₁₂H₈Cl₂ (M⁺) 222.0003, obsd. 222.0004.

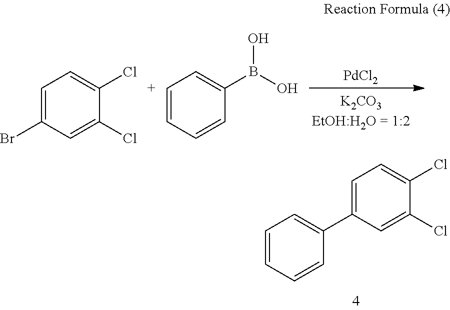

### EXAMPLE 5

### Synthesis of Compound 5

Compound 4 (0.58 g, 1.53 mmol), Bis(dibenzylideneacetone)palladium(0) (Pd(dba)₂, 0.15 g, 0.15 mmol), tri-tert-butylphosphonium tetrafluoroborate (0.15 g, 0.30 mmol), and sodium tert-butoxide (NaO^{t}Bu, 0.60 g, 3.83 mmol) were provided in a 25 ml two-neck bottle in an inert atmosphere. The dehydrated and deoxygenated toluene (3.80 ml) and aniline (0.35 ml, 3.83 mmol) were added into the bottle. The mixture was heated to 110° C. for 18 hours. After cooling to the room temperature, the solution was filtered by diatomaceous earth. The filtrate was collected and extracted with aqueous ammonium chloride solution. The organic layer was dried with anhydrous MgSO₄ and concentrated under vacuum. The crude was purified through by column chromatography with n-hexane/DCM=3/1 as eluent to obtain compound 5 (0.43 g, yield: 84%) as a white solid. The foregoing reaction is shown in the Reaction Formula (5).

Spectral data as follow: ¹H NMR (400 MHz, DMSO-d₆): δ 7.55(d, J=7.4 Hz, 2H), 7.50(s, J=2.0 Hz, 1H), 7.43-7.39(m, 4H), 7.34-7.27(m, 2H), 7.23-7.18(m, 5H),6.44(d, J=7.6 Hz, 4H), 6.81-6.76(m, 2H); ¹³C NMR (100 MHz, DMSO-d₆): δ 144.44, 144.09, 140.20, 134.50, 134.34, 133.52, 129.10, 129.05, 128.89, 126.72, 126.03, 120.40, 119.52, 119.36, 119.16, 117.96, 116.66, 116.33; HRMS(FAB) m/z calcd for C₂₄H₂₀N₂(M⁺)336.1626, obsd. 336.1629.

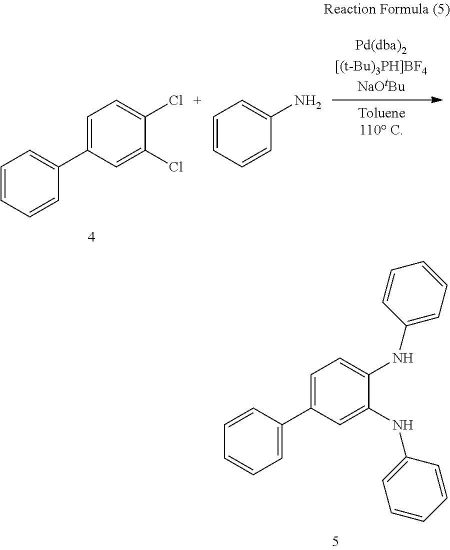

### EXAMPLE 6

### Synthesis of Compound 6

1-bromo-2,3-dichlorobenzene (1.00 g, 4.43 mmol), 2-Naphthaleneboronic acid (0.81 g, 4.71 mmol), potassium carbonate (K₂CO₃, 1.38 g, 10.00 mmol), and palladium(II) chloride (PdCl₂, 4.05 mg, 0.02 mmol) were provided in a 100 ml single-neck bottle. After adding with 5 ml ethanol and 10 ml deionized water, the solution was stirred for a half hour at room temperature. The solution was then extracted with DCM/potassium carbonate aqueous solution. The organic layer was dried with anhydrous MgSO₄ and concentrated under vacuum. The crude was purified through by column chromatography with n-hexane as eluent to obtain compound 6 (0.80 g, yield: 66%) as a white solid. The foregoing reaction is shown in the Reaction Formula (6).

Spectral data as follow: ¹H NMR (400 MHz, CD₂Cl₂): δ 7.90-7.87(m, 4H), 7.58-7.52(m, 4H), 7.38-7.32(m, 2H); ¹³C NMR (100 MHz, CDCl₃): δ 142.81, 136.80, 133.62, 133.04, 132.73, 131.32, 129.71, 129.51, 128.26, 128.17, 127.72, 127.58, 127.26, 127.19, 126.44, 126.38; HRMS(FAB) m/z calcd for C₁₆H₁₀Cl₂ (M⁺) 272.0160, obsd. 272.0159.

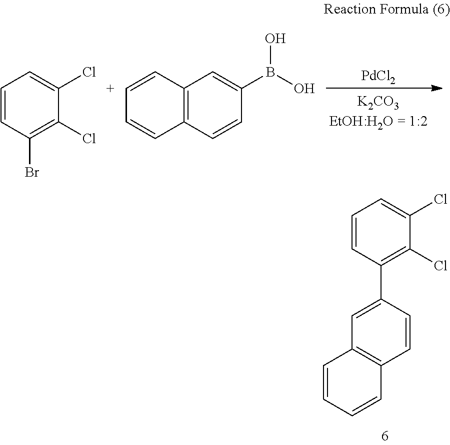

### EXAMPLE 7

### Synthesis of Compound 7

Compound 6 (0.67 g, 2.46 mmol), Bis(dibenzylideneacetone)palladium(0) (Pd(dba)₂, 0.14 g, 0.24 mmol), tri-tert-butylphosphonium tetrafluoroborate (0.14 g, 0.49 mmol), and sodium tert-butoxide (NaO^{t}Bu, 0.59 g, 6.15 mmol) were provided in a 25 ml two-neck bottle in an inert atmosphere. The dehydrated and deoxygenated toluene (12 ml) and aniline (0.57 ml, 6.25 mmol) were added into the bottle. The mixture was heated to 110° C. for 18 hours. After cooling to the room temperature, the solution was filtered by diatomaceous earth. The filtrate was collected and extracted with aqueous ammonium chloride solution. The organic layer was dried with anhydrous MgSO₄ and concentrated under vacuum. The crude was purified through by column chromatography with n-hexane/DCM=4/1 as eluent to obtain compound 7 (0.80 g, yield: 84%) as a white solid. The foregoing reaction is shown in the Reaction Formula (7).

Spectral data as follow: ¹H NMR (400 MHz, CDCl₃): δ 7.82-7.68(m, 4H), 7.48-7.43(m, 2H), 7.41(dd, J₁=8.2 Hz, J₂=1.2 Hz, 1H), 7.33(dd, J₁=8.4 Hz, J₂=1.6 Hz, 1H), 7.27(t, J=7.9 Hz, 2H), 7.21-7.10(m, 5H), 6.99-6.94(m, 2H), 6.82(t, J=7.28 Hz, 1H), 6.62(d, J=8.0 Hz, 2H), 6.13(br, 1H), 5.14(br, 1H); ¹³C NMR (100 MHz, CDCl₃): δ 145.98, 142.25, 140.87, 139.67, 136.82, 133.29, 132.52, 129.41, 129.26, 128.07, 127.83, 127.59, 127.27, 126.69, 126.19, 126.05, 121.81, 121.72, 119.77, 119.56, 114.68, 113.97; HRMS(FAB) m/z calcd for C₂₈H₂₂N₂ (M⁺) 386.1783, obsd. 386.1781.

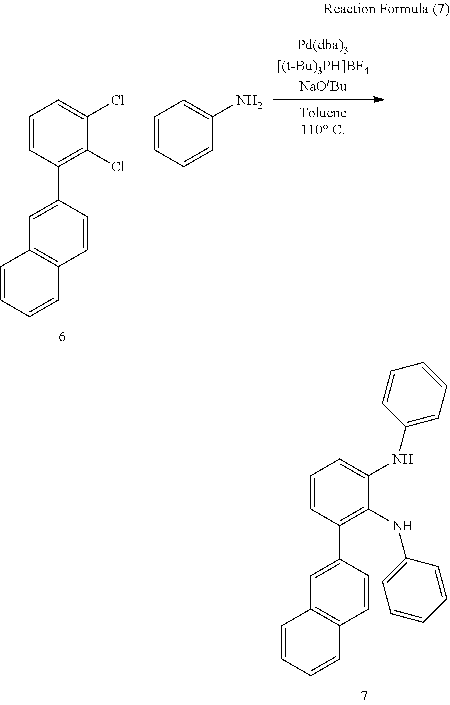

### EXAMPLE 8

### Synthesis of Compound 8

1-bromo-3,4-dichlorobenzene (1.00 g, 4.43 mmol), 2-Naphthaleneboronic acid (0.81 g, 4.71 mmol), potassium carbonate (K₂CO₃, 1.38 g, 10.00 mmol), and palladium(II) chloride (PdCl₂, 4.01 mg, 0.02 mmol) were provided in a 100 ml single-neck bottle. After adding with 5 ml ethanol and 15 ml deionized water, the solution was stirred for a half hour at room temperature. The solution was then extracted with DCM/potassium carbonate aqueous solution. The organic layer was dried with anhydrous MgSO₄ and concentrated under vacuum. The crude was purified through by column chromatography with n-hexane as eluent to obtain compound 8 (0.90 g, yield: 75%) as a white solid. The foregoing reaction is shown in the Reaction Formula (8).

Spectral data as follow: ¹H NMR (400 MHz, CDCl₃): δ 7.98(d, J=0.3 Hz, 1H), 7.92-7.84(m, 3H), 7.79(t, J=1.2 Hz, 3H), 7.65(dd, J₁=8.5Hz, J₂=1.8Hz, 1H), 7.53-7.49(m, 4H); ¹³C NMR (100 MHz, CDCl₃): δ 141.16, 136.02,133.52, 132.93, 132.89, 131.75, 129.17, 128.79, 128.24, 127.68, 126.68, 126.62, 126.59, 125.95, 124.87; HRMS(FAB) m/z calcd for C₁₆H₁₀Cl₂ (M⁺) 272.0161, obsd. 272.0160.

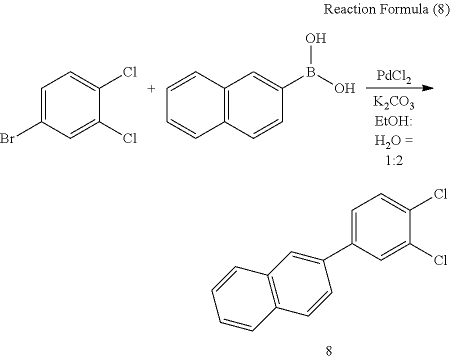

### EXAMPLE 9

### Synthesis of Compound 9

Compound 8 (0.82 g, 3.00 mmol), Bis(dibenzylideneacetone)palladium(0) (Pd(dba)₂, 0.17 g, 0.30 mmol), tri-tert-butylphosphonium tetrafluoroborate (0.17 g, 0.60 mmol) and sodium tert-butoxide (NaO^{t}Bu, 0.72 g, 7.50 mmol) were provided in a 25 ml two-neck bottle in an inert atmosphere. The dehydrated and deoxygenated toluene (15 ml) and aniline (0.70 ml, 7.68 mmol) were added into the bottle. The mixture was heated to 110° C. for 18 hours. After cooling to the room temperature, the solution was filtered by diatomaceous earth. The filtrate was collected and extracted with aqueous ammonium chloride solution. The organic layer was dried with anhydrous MgSO₄ and concentrated under vacuum. The crude was purified through by column chromatography with n-hexane/DCM=4/1 as eluent to obtain compound 9 (0.83 g, yield: 72%) as a white solid. The foregoing reaction is shown in the Reaction Formula (9).

Spectral data as follow: ¹H NMR (400 MHz, DMSO-d₆): δ 8.09(s, 1H), 7.96(d, J=8.4 Hz, 2H), 7.91(d, J=7.6 Hz, 1H), 7.76(d, J=8.4 Hz, 1H), 7.66(s, 1H), 7.51-7.38(m, 6H), 7.24-7.19(m, 4H), 7.07-7.02(m, 4H), 6.83-6.76(m, 2H); ¹³C NMR (100 MHz, DMSO-d₆): δ 144.60, 143.97, 137.53, 134.79, 134.32, 133.40, 133.15, 131.89, 129.10, 129.06, 128.37, 128.00, 127.43, 126.31, 125.72, 124.82, 124.09, 120.94, 119.48, 119.32, 119.04, 118.66, 116.82, 116.14; HRMS(FAB) m/z calcd for C₂₈H₂₂N₂ (M⁺) 386.1783, obsd. 386.1782

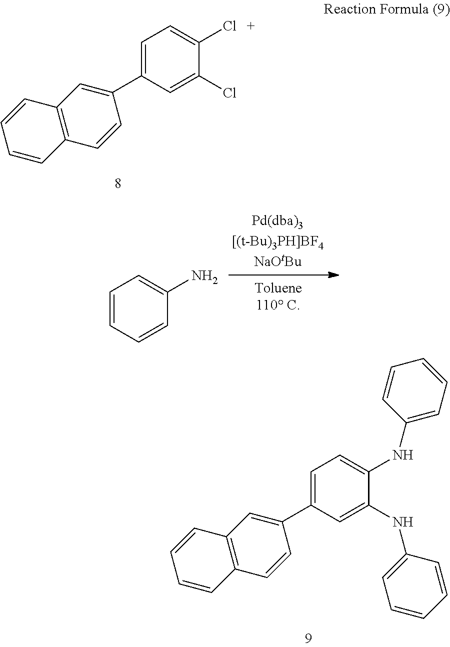 [SMILES: Clc1ccc(-c2ccc3ccccc3c2)cc1Cl ; Nc1ccccc1 ; c1ccc(Nc2ccc(-c3ccc4ccccc4c3)cc2Nc2ccccc2)cc1]

### EXAMPLE 10

### Synthesis of Compound 10

1,2-Dibromo-4-fluorobenzene (6.82 g, 26.86 mmol), Carbazole (4.71 g, 28.20 mmol) and Cesium carbonate (Cs₂CO₃, 13.13 g, 40.29 mmol) were provided in a 250 ml single-neck bottle. The mixture was added with 34 ml dimethylformamide (dried by calcium hydride) and heated to 130° C. for 18 hours. After cooling to the room temperature, dimethylformamide was removed under vacuum. The residual was added with DCM and filtered. The filtrate was dried with anhydrous MgSO₄ and concentrated under vacuum. The crude was purified through by column chromatography with n-hexane/DCM=8/1 as eluent to obtain compound 10 (8.02 g, yield: 75%) as a white solid. The foregoing reaction is shown in the Reaction Formula (10).

Spectral data as follow: ¹H NMR (400 MHz, DMSO-d₆): δ 8.24(d, J=7.6 Hz, 2H), 8.05-8.02(m, 2H), 7.60(dd, J₁=8.4 Hz, J₂=2.4 Hz, 1H), 7.46-7.40(m, 4H), 7.33-7.29(m, 2H); ¹³C NMR (100 MHz, DMSO-d₆): δ 139.77, 137.36, 135.08, 131.66, 127.72,126.43, 125.11, 122.93, 122.75, 120.55, 120.51; HRMS(FAB) m/z calcd for C₁₈H₁₁Br₂N (M⁺)398.9258, obsd. 398.9259.

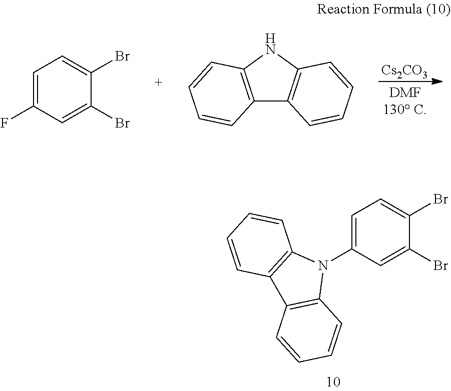

### EXAMPLE 11

### Synthesis of Compound 11

Compound 10 (1.5 g, 3.77 mmol), Bis(dibenzylideneacetone)palladium(0) (Pd(dba)₂, 0.22 g, 0.38 mmol), tri-tert-butylphosphonium tetrafluoroborate (0.22 g, 0.75 mmol) and sodium tert-butoxide (NaO^{t}Bu, 1.08 g, 11.25 mmol) were provided in a 25 ml two-neck bottle in an inert atmosphere. The dehydrated and deoxygenated toluene (25 ml) and aniline (1.05 ml, 11.52 mmol) were added into the bottle. The mixture was heated to 110° C. for 18 hours. After cooling to the room temperature, the solution was filtered by diatomaceous earth. The filtrate was collected and extracted with aqueous ammonium chloride solution. The organic layer was dried with anhydrous MgSO₄ and concentrated under vacuum. The crude was purified through by column chromatography with n-hexane/DCM=3/1 as eluent to obtain compound 11 (1.12 g, yield: 69%) as a white solid. The foregoing reaction is shown in the Reaction Formula (11).

Spectral data as follow: ¹H NMR (400 MHz, DMSO-d₆): δ 8.21(d, J=7.7 Hz, 2H), 7.57(s, 1H), 7.53(s,1H), 7.48 (d, J=8.4 Hz, 1H), 7.44 (d, J=4.0 Hz, 4H), 7.31-7.23(m, 5H), 7.19(t, J=7.8 Hz, 2H), 7.12-7.06(m, 5H), 6.83(t, J=7.3 Hz, 1H), 6.78(t, J=7.3 Hz, 1H); ¹³C NMR (100 MHz, DMSO-d₆): δ 144.09, 143.57, 140.32, 136.11, 133.53, 130.25, 129.08, 126.13, 122.45, 120.42, 120.20, 119.99, 119.72, 119.53, 119.44, 117.41, 116.79, 116.28, 109.65; HRMS(FAB) m/z calcd for C₃₀H₂₃N₃(M⁺) 425.1892, obsd. 425.1895.

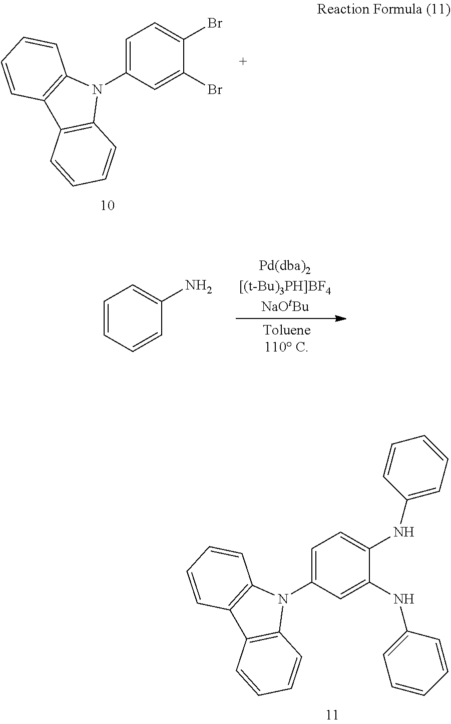 [SMILES: Brc1ccc(-n2c3ccccc3c3ccccc32)cc1Br ; Nc1ccccc1 ; c1ccc(Nc2ccc(-n3c4ccccc4c4ccccc43)cc2Nc2ccccc2)cc1]

### EXAMPLE 12

### Synthesis of Compound 12

1,2-Dibromo-4,5-difluorobenzene (10.00 g, 36.78 mmol), Carbazole (13.50 g, 80.84 mmol) and Cesium carbonate (Cs₂CO₃, 30.00 g, 91.95 mmol)were provided in a 500 ml single-neck bottle. The mixture was added with 92 ml dimethylformamide (dried by calcium hydride) and heated to 130° C. for 18 hours. After cooling to the room temperature, dimethylformamide was removed under vacuum. The residual was added with DCM and filtered. The organic layer was concentrated under vacuum. The crude was hot washed by ethyl acetate and filtered to obtain compound 12 (16.62 g, yield: 80%) as a white solid. The foregoing reaction is shown in the Reaction Formula (12).

Spectral data as follow: ¹H NMR (400 MHz, CDCl₃): δ 8.07(s, 1H), 7.78-7.76(m, 4H), 7.13-7.11(m, 4H), 7.06-7.04(m, 8H; ¹³C NMR (100 MHz, CDCl₃): δ 139.33, 134.82, 134.47, 125.68, 124.32, 123.65, 120.45, 120.04, 109.38; HRMS(FAB) m/z calcd for C₃₀H₁₈Br₂N₂(M⁺)563.9837, obsd. 563.9840.

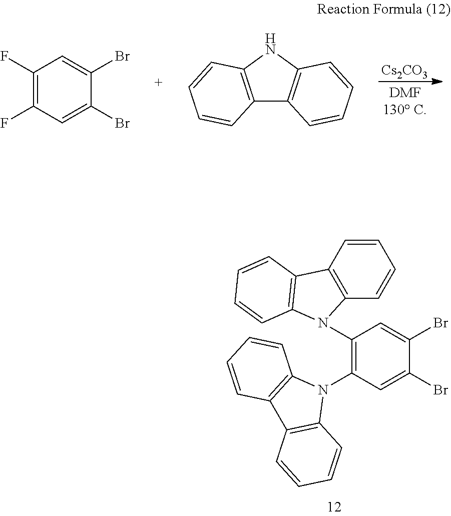

### EXAMPLE 13

### Synthesis of Compound 13

Compound 12 (1.75 g, 3.10 mmol), Bis(dibenzylideneacetone)palladium(0) (Pd(dba)₂, 0.18 g, 0.31 mmol), tri-tert-butylphosphonium tetrafluoroborate (0.18 g, 0.62 mmol) and sodium tert-butoxide (NaO^{t}Bu, 0.74 g, 7.71 mmol) were provided in a 25 ml two-neck bottle in an inert atmosphere. The dehydrated and deoxygenated toluene (25 ml) and aniline (1.05 ml, 11.52 mmol) were added into the bottle. The mixture was heated to 110° C. for 18 hours. After cooling to the room temperature, the solution was filtered by diatomaceous earth. The filtrate was collected and extracted with aqueous ammonium chloride solution. The organic layer was dried with anhydrous MgSO₄ and concentrated under vacuum. The crude was purified through by column chromatography with n-hexane/DCM=2/1 as eluent to obtain compound 13 (1.02 g, yield: 55%) as a white solid. The foregoing reaction is as shown in the Reaction Formula (13).

Spectral data as follow: ¹H NMR (400 MHz, DMSO-d₆): δ 7.89(d, J=7.6 Hz, 4H), 7.80(s, 2H), 7.39-7.36(m, 6H), 7.22(d, J=4.1 Hz, 8H), 7.12(t, J=7.2 Hz, 4H), 7.02(t, J=7.2 Hz, 4H), 6.83-6.79(m, 2H); ¹³C NMR (100 MHz, DMSO-d₆): δ 143.17, 140.00, 135.51, 129.19, 126.24, 125.55, 122.47, 120.54, 120.03, 119.60, 118.05, 109.89; HRMS(FAB) m/z calcd for C₄₂H₃₀N₄(M⁺)590.2470, obsd. 590.2463

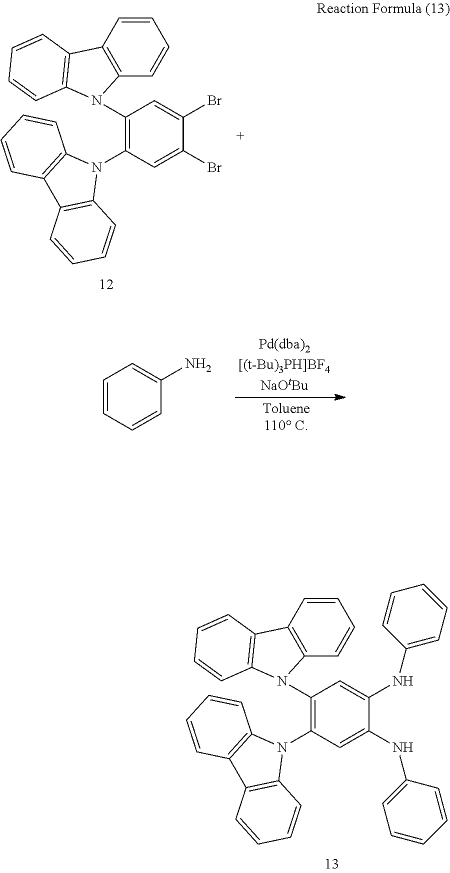 [SMILES: Brc1cc(-n2c3ccccc3c3ccccc32)c(-n2c3ccccc3c3ccccc32)cc1Br ; Nc1ccccc1 ; c1ccc(Nc2cc(-n3c4ccccc4c4ccccc43)c(-n3c4ccccc4c4ccccc43)cc2Nc2ccccc2)cc1]

### EXAMPLE 14

### Synthesis of Compound 14

2-chloro,6-fluorobromobenzene (1.00 g, 4.78 mmol), Carbazole (0.83 g, 4.97 mmol) and sodium tert-butoxide (NaO^{t}Bu, 0.67 g, 6.98 mmol) were provided in a 50 ml two-neck bottle. The mixture was added with 12 ml dimethylformamide (dried by calcium hydride) and heated to 130° C. for 18 hours. After cooling to the room temperature, dimethylformamide was removed under vacuum. The residual was added with DCM and filtered. The filtrate was dried with anhydrous MgSO₄ and concentrated under vacuum. The crude was purified through by column chromatography with n-hexane/DCM=8/1 as eluent to obtain compound 14 (1.30 g, yield: 76%) as a white solid. The foregoing reaction is shown in the Reaction Formula (14).

Spectral data as follow: ¹H NMR (400 MHz, CDCl₃): δ 8.14(d, J=8.0 Hz, 2H), 7.66(dd, J₁=8.0 Hz, J₂=1.6 Hz, 1H), 7.46(t, J=8.0 Hz, 1H), 7.41-7.38(m, 3H), 7.30(t, J=8.0 Hz, 2H), 7.04(d, J=8.0 Hz, 2H); ¹³C NMR (100 MHz, CDCl₃): δ 140.57, 138.81, 136.87, 130.62, 129.28, 128.92, 126.05, 124.99, 123.31, 120.40, 120.21, 109.93; HRMS(FAB) m/z calcd for C₁₈H₁₁BrClN(M⁺) 311.9763, obsd. 354.9765.

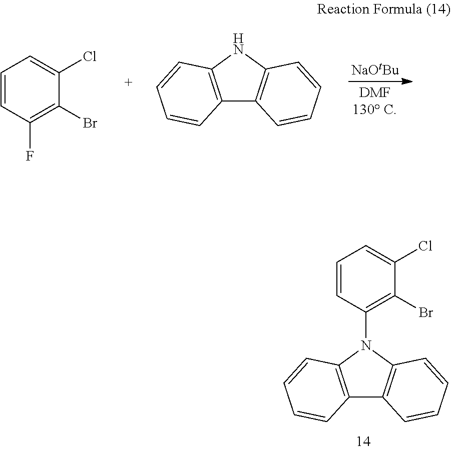 [SMILES: Fc1cccc(Cl)c1Br ; c1ccc2c(c1)[nH]c1ccccc12 ; Clc1cccc(-n2c3ccccc3c3ccccc32)c1Br ; "NaOtBu"]

### EXAMPLE 15

### Synthesis of Compound 15

Compound 12 (0.4 g, 1.13 mmol), 1,1′-Bis(diphenylphosphino)ferrocene (0.06 g, 0.11 mmol), palladium acetate (0.13 g, 0.11 mmol) and sodium tert-butoxide (NaO^{t}Bu, 0.12 g, 0.13 mmol) were provided in a 25 ml two-neck bottle in an inert atmosphere. The dehydrated and deoxygenated toluene (3 ml) and aniline (0.11 ml, 1.24 mmol) were added into the bottle. The mixture was heated to 110° C. for 18 hours. After cooling to the room temperature, the solution was filtered by diatomaceous earth. The filtrate was collected and extracted with aqueous ammonium chloride solution. The organic layer was dried with anhydrous MgSO₄ and concentrated under vacuum. The crude was purified through by column chromatography with n-hexane/DCM=6/1 as eluent to obtain compound 15 (0.22 g, yield: 48%) as a white solid. The foregoing reaction is shown in the Reaction Formula (15).

Spectral data as follow: ¹H NMR (400 MHz, CDCl₃): δ 8.10(d, J=8.0 Hz, 1H), 7.66 (dd, J₁=8.0 Hz, J₂=1.6 Hz, 1H), 7.47-7.39(m, 3H), 7.39-7.22 (m, 5H), 6.71(t, J=8.0 Hz, 2H), 6.59(t, J=8.0 Hz, 2H), 6.39(d, J=8.0 Hz, 2H), 5.81(s, 1H); ¹³C NMR (100 MHz, CDCl₃): δ 141.15, 139.74, 137.43, 129.78, 129.75, 128.77, 128.05, 127.62, 125.62, 123.28, 122.70, 121.55, 119.99, 119.81, 118.37, 109.99; HRMS(ESI) m/z calcd for C₂₄H₁₇BrN₂(MH⁺) 369.1159, obsd.369.1168.

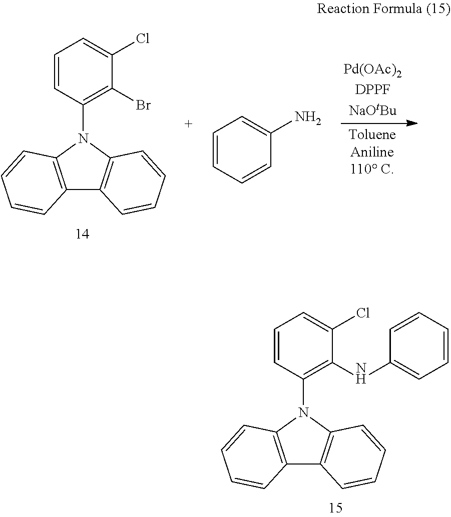 [SMILES: Clc1cccc(-n2c3ccccc3c3ccccc32)c1Br ; Nc1ccccc1 ; Clc1cccc(-n2c3ccccc3c3ccccc32)c1Nc1ccccc1]

### EXAMPLE 16

### Synthesis of Compound 16

Compound 15 (0.50 g, 1.36 mmol), Bis(dibenzylideneacetone)palladium(0) (Pd(dba)₂, 0.078 g, 0.14 mmol), tri-tert-butylphosphonium tetrafluoroborate (0.079 g, 0.27 mmol) and sodium tert-butoxide (NaO^{t}Bu, 0.20 g, 2.04 mmol) were provided in a 25 ml two-neck bottle in an inert atmosphere. The dehydrated and deoxygenated toluene (3.50 ml) and aniline (0.19 ml, 2.08 mmol) were added into the bottle. The mixture was heated to 110° C. for 18 hours. After cooling to the room temperature, the solution was filtered by diatomaceous earth. The filtrate was collected and extracted with aqueous ammonium chloride solution. The organic layer was dried with anhydrous MgSO₄ and concentrated under vacuum. The crude was purified through by column chromatography with n-hexane/DCM=2/1 as eluent to obtain compound 16 (0.35 g, yield: 61%) as a white solid. The foregoing reaction is shown in the Reaction Formula (16).

Spectral data as follow: ¹H NMR (400 MHz, DMSO-d₆): δ 8.03(d, J=7.6 Hz, 2H), 7.47(dd, J₁=8.0 Hz, J₂=0.4 Hz, 1H), 7.40 (s, 1H), 7.31(t, J=7.6 Hz, 2H), 7.28-7.22(m, 5H), 7.17-7.12(m, 4H), 7.08(s, 1H), 6.98(dd, J₁=8.0 Hz, J₂=0.4 Hz, 1H), 6.87(t, J=7.6 Hz, 1H), 6.56(t, J=8.0 Hz, 1H), 6.27-6.23(m, 3H); ¹³C NMR (100 MHz, DMSO-d₆): δ 144.20, 143.12, 140.90, 139.79, 133.26, 129.15, 128.46, 127.55, 125.28, 122.68, 120.47, 120.36, 119.97, 119.30, 117.75, 117.58, 116.46, 113.99, 110.31; HRMS(FAB) m/z calcd for C₃₀H₂₃N₃(M⁺)425.1892, obsd. 425.1894.

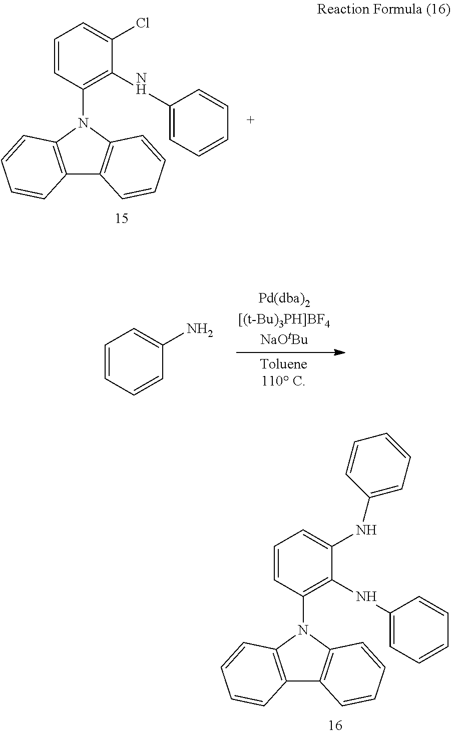 [SMILES: Clc1cccc(-n2c3ccccc3c3ccccc32)c1Nc1ccccc1 ; Nc1ccccc1 ; c1ccc(Nc2cccc(-n3c4ccccc4c4ccccc43)c2Nc2ccccc2)cc1]

### EXAMPLE 17

### Synthesis of Compound 17 (NS)

Calcium hydride (1.30 g, 30.95 mmol) was provided in a 50 ml tri-neck bottle and two sets of dropping funnels were set in an inert atmosphere. The deoxygenated and dehydrated DCM (30 ml) was added into the reaction bottle. N¹,N²-diphenylbenzene-1,2-diamine (compound 1, 1.60 g, 6.15 mmol) was added in one dropping funnel. The dichlorophenylborane (0.90 ml, 7.20 mmol) was added into the other dropping funnel. Each of the dropping funnels was added with 18 ml DCM and slowly dropped into the bottle under ice bath. One hour later, the mixture was warmed to room temperature and stirred for 5 hours. The mixture was filtered and the filtrate was extracted with aqueous potassium carbonate solution. The organic layer was dried with anhydrous MgSO₄ and concentrated under vacuum. The crude was washed by ether to obtain compound 17 (NS, 1.75 g, yield: 82%) as a white solid. The foregoing reaction is shown in the Reaction Formula (17).

Spectral data as follow: m.p.=184° C.; ¹H NMR (400 MHz, CDCl₃): δ 7.44-7.40(m, 4H), 7.34-7.31(m, 6H), 7.23-7.18(tt, J₁=7.1 Hz, J₂=1.7 Hz, 1H), 7.14-7.07(m, 6H), 7.05-7.01(m, 2H); ¹³C NMR (100 MHz, CDCl₃): δ 140.36, 137.79, 134.68, 129.24, 128.56, 127.78, 127.30, 126.29, 119.97, 110.10; HRMS(FAB) m/z calcd for C₂₄H₁₉BN₂(M⁺) 346.1641, obsd. 346.1642

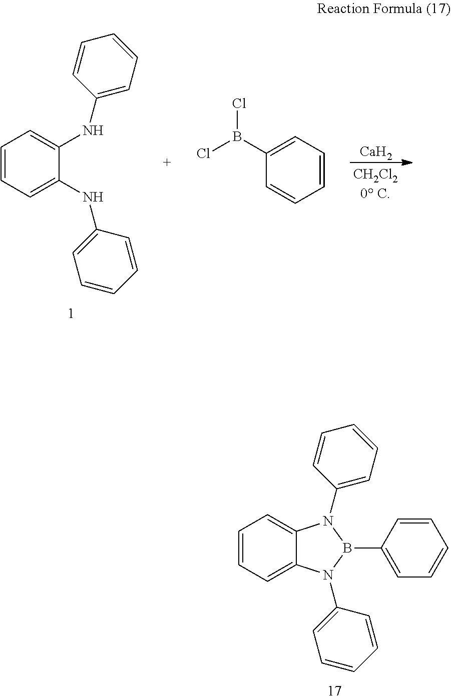

### EXAMPLE 18

### Synthesis of Compound 18 (mPh)

Calcium hydride (0.50 g, 11.90 mmol) was provided in a 50 ml tri-neck bottle and two sets of dropping funnels were set in an inert atmosphere. The deoxygenated and dehydrated DCM (15 ml) was added into the reaction bottle. The N³,N⁴-diphenyl-[1,1′-biphenyl]-3,4-diamine (compound 5, 0.70 g, 2.08 mmol) was added in one dropping funnel. The dichlorophenylborane (0.35 ml, 2.70 mmol) was added into the other dropping funnel. Each of the dropping funnels was added with 7.50 ml DCM and slowly dropped into the bottle under ice bath. One hour later, the mixture was warmed to room temperature and stirred for 5 hours. The mixture was filtered and the filtrate was extracted with aqueous potassium carbonate solution. The organic layer was dried with anhydrous MgSO₄ and concentrated under vacuum. The crude was washed by ether to obtain compound 18 (mPh, 0.71 g, yield: 81%) as a white solid. The foregoing reaction is shown in the Reaction Formula (18).

Spectral data as follow: m.p.=210° C.; ¹H NMR (400 MHz, CD₂Cl₂): δ 7.57-7.55(m, 2H), 7.49-7.45(m, 4H), 7.41-7.35(m, 8H), 7.30-7.19(m, 6H), 7.14-7.11(m, 3H); ¹³C NMR (100 MHz, CD₂Cl₂): δ 142.54, 140.96, 140.87, 139.07, 138.12, 135.16, 134.20, 129.92, 129.88, 129.23, 129.17, 128.44, 128.30, 127.88, 127.57, 127.06, 127.01, 119.76, 110.72, 109.30; HRMS(FAB) m/z calcd for C₃₀H₂₃BN₂(M⁺) 422.1954, obsd. 422.1956; Anal. Calcd for C₃₀H₂₃BN₂: C, 85.32; H, 5.49; B, 2.56; N, 6.63. Found: C, 85.10; H, 5.64; N, 6.56.

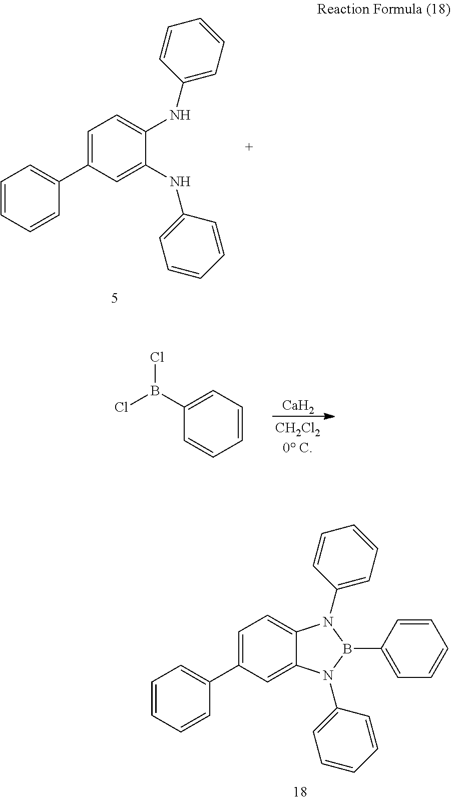

### EXAMPLE 19

### Synthesis of Chemical Formula (1)-Compound 19 (mNp)

Calcium hydride (0.35 g, 8.33 mmol) was provided in a 50 ml tri-neck bottle and two sets of dropping funnels were set in an inert atmosphere. The deoxygenated and dehydrated DCM (11 ml) was added into the reaction bottle. 4-(naphthalen-2-yl)-N¹,N²-diphenylbenzene-1,2-diamine (compound 9, 0.65 g, 1.67 mmol) was added in one dropping funnel. The dichlorophenylborane (0.27 ml, 2.08 mmol) was added into the other dropping funnel. Each of the dropping funnels was added with 5.5 ml DCM and slowly dropped into the bottle under ice bath. One hour later, the mixture was warmed to room temperature and stirred for 5 hours. The mixture was filtered and the filtrate was extracted with aqueous potassium carbonate solution. The organic layer was dried with anhydrous MgSO₄ and concentrated under vacuum. The crude was washed by ether to obtain compound 19 (mNp, Chemical Formula (1), 0.61 g, yield: 77%) as a white solid. The foregoing reaction is shown in the Reaction Formula (19).

Spectral data as follow: m.p.=224° C.; ¹H NMR (400 MHz, CDCl₃): δ 7.94(s, 1H), 7.85-7.80(m, 3H), 7.69(dd, J₁=8.5Hz, J₂=1.8Hz, 1H), 7.45-7.71(m, 6H), 7.39-7.33(m, 8H), 7.20-7.18(m, 1H), 7.16(d, J=8.28Hz, 1H), 7.13-7.07(m, 4H); ¹³C NMR (100 MHz, CDCl₃): δ 140.32, 140.24, 139.45, 138.42, 137.69, 133.72, 129.41, 129.34, 128.68, 128.15, 127.99, 127.86, 127.75, 127.57, 127.35, 126.47, 126.43, 126.12, 126.05, 125.48, 125.32, 119.65, 110.35, 109.16; HRMS(FAB) m/z calcd for C₃₄H₂₅BN₂ (M^{|}) 472.2111, obsd. 472.2117; Anal. Calcd for C₃₄H₂₅BN₂: C, 86.45; H, 5.33; B, 2.29; N, 5.93. Found: C, 86.54; H, 5.33; N, 5.91.

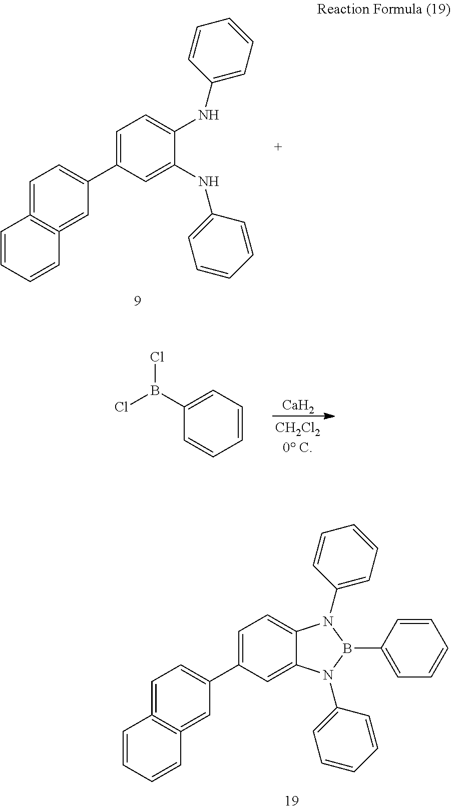

### EXAMPLE 20

### Synthesis of Chemical Formula (2)-Compound 20 (oPh)

Calcium hydride (0.21 g, 5 mmol) was provided in a 25 ml tri-neck bottle and two sets of dropping funnels were set in an inert atmosphere. The deoxygenated and dehydrated DCM (6 ml) was added into the reaction bottle. The N²,N³-diphenyl-[1,1′-biphenyl]-2,3-diamine (compound 3, 0.34 g, 1.01 mmol) was added in one dropping funnel. The dichlorophenylborane (0.15 ml, 1.20 mmol) was added into the other dropping funnel. Each of the dropping funnels was added with 3 ml DCM and slowly dropped into the bottle under ice bath. One hour later, the mixture was warmed to room temperature and stirred for 5 hours. The mixture was filtered and the filtrate was extracted with aqueous potassium carbonate solution. The organic layer was dried with anhydrous MgSO₄ and concentrated under vacuum. The crude was washed by ether to obtain compound 20 (oPh, Chemical Formula (2), 0.34 g, yield: 80%) as a white solid. The foregoing reaction is shown in the Reaction Formula (20).

Spectral data as follow: m.p.=161° C.; ¹H NMR (400 MHz, CD₂Cl₂): δ 7.46-7.43(m, 2H), 7.37-7.33(m, 3H), 7.19-7.15(m, 1H), 7.09-7.03(m, 6H), 6.99-6.91(m, 6H), 6.89-6.81(m, 5H); ¹³C NMR (100 MHz, CD₂Cl₂): δ 149.37, 141.04, 139.97, 139.65, 135.05, 134.05, 129.84, 129.80, 128.81, 128.66, 128.59, 128.27, 127.87, 127.62, 127.55, 126.99, 126.21, 125.79, 124.26, 120.08, 109.79; HRMS(FAB) m/z calcd for C₃₀H₂₃BN₂ (M⁺) 422.1954, obsd. 422.1958; Anal. Calcd for C₃₀H₂₃BN₂: C, 85.32; H, 5.49; B, 2.56; N, 6.63. Found: C, 85.23; H, 5.53; N, 6.60.

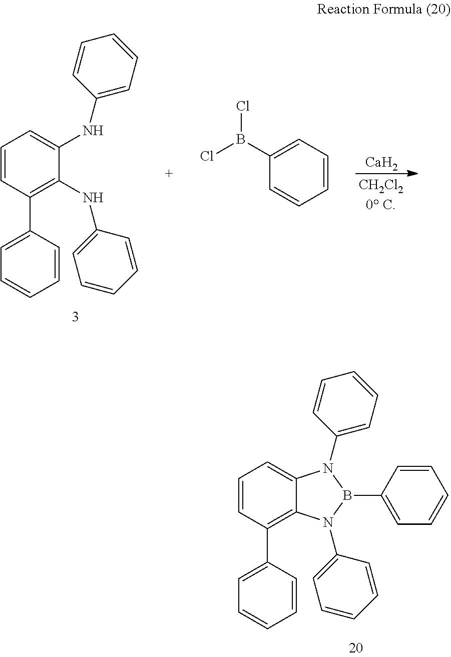

### EXAMPLE 21

### Synthesis of Chemical Formula (3)-Compound 21 (oNp)

Calcium hydride (0.33 g, 7.85 mmol) was provided in a 50 ml tri-neck bottle and two sets of dropping funnels were set in an inert atmosphere. The deoxygenated and dehydrated DCM (12 ml) was added into the reaction bottle. The 3-(naphthalen-2-yl)-N¹,N²-diphenylbenzene-1,2-diamine (compound 7, 0.60 g, 1.55 mmol) was added in one dropping funnel. The dichlorophenylborane (0.30 ml, 1.87 mmol) was added into the other dropping funnel. Each of the dropping funnels was added with 5.70 ml DCM and slowly dropped into the bottle under ice bath. One hour later, the mixture was warmed to room temperature and stirred for 5 hours. The mixture was filtered and the filtrate was extracted with aqueous potassium carbonate solution. The organic layer was dried with anhydrous MgSO₄ and concentrated under vacuum. The crude was washed by ether to obtain compound 21 (oNp, Chemical Formula (3), 0.64 g, yield: 87%) as a white solid. The foregoing reaction is shown in the Reaction Formula (21).

Spectral data as follow: m.p.=190° C.; ¹H NMR (400 MHz, CDCl₃): δ 7.67-7.65(m, 1H), 7.57-7.54(m, 1H), 7.45-7.40(m, 3H), 7.37-7.31(m, 6H), 7.13-7.07(m, 4H), 7.04-6.97(m, 5H), 6.79(d, J=8.2 Hz, 2H), 6.59-6.50(m, 3H); ¹³C NMR (100 MHz, CDCl₃): δ 140.61, 140.40, 138.99, 136.92, 134.62, 133.79, 132.48, 131.57, 129.26, 128.29, 128.06, 127.76, 127.53, 127.29, 127.08, 126.40, 126.25, 125.42, 125.30, 125.09, 123.85, 119.55, 109.49; HRMS(FAB) m/z calcd for C₃₄H₂₅BN₂ (M⁺) 472.2111, obsd. 472.2114; Anal. Calcd for C₃₄H₂₅BN₂: C, 86.45; H, 5.33; B, 2.29; N, 5.93. Found: C, 86.42; H, 5.32; N, 5.87.

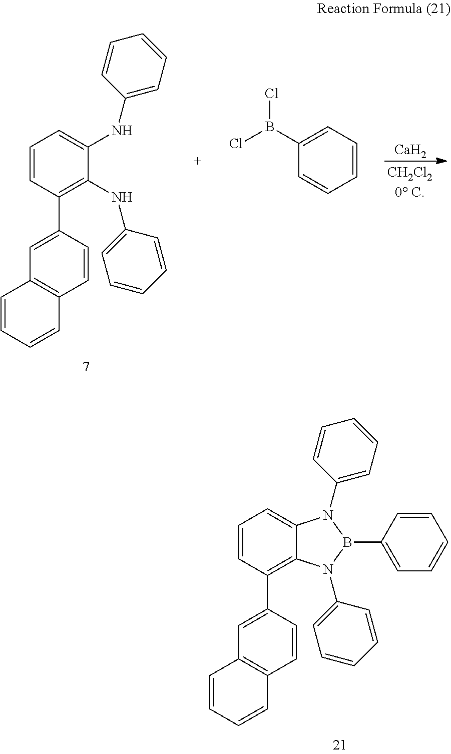

### EXAMPLE 22

### Synthesis of Compound 22 (mCb)

Calcium hydride (0.39 g, 9.40 mmol) was provided in a 50 ml tri-neck bottle and two sets of dropping funnels were set in an inert atmosphere. The deoxygenated and dehydrated DCM (14 ml) was added into the reaction bottle. The 4-(9H-carbazol-9-yl)-N¹,N²-diphenylbenzene-1,2-diamine (compound 11, 0.80 g, 1.88 mmol) was added in one dropping funnel. The dichlorophenylborane (0.29 ml, 2.26 mmol) was added into the other dropping funnel. Each of the dropping funnels was added with 7 ml DCM and slowly dropped into the bottle under ice bath. One hour later, the mixture was returned to room temperature and stirred for 10 hours. The mixture was filtered and the filtrate was extracted with aqueous potassium carbonate solution. The organic layer was dried with anhydrous MgSO₄ and concentrated under vacuum. The crude was washed by ether to obtain compound 22 (mCb, 0.70 g, yield: 73%) as a white solid. The foregoing reaction is shown in the Reaction Formula (22).

Spectral data as follow: m.p.=291° C.; ¹H NMR (400 MHz, CD₂Cl₂): δ 8.12(dd, J₁=7.7 Hz, J₂=0.8 Hz, 2H), 7.51-7.48(m, 2H), 7.43-7.31(m, 11H), 7.29-7.20(m, 7H), 7.17-7.11(m, 4H); ¹³C NMR (100 MHz, CD₂Cl₂): δ 142.26, 140.73, 140.50, 139.47, 138.04, 130.56, 130.00, 129.97, 128.33, 128.14, 127.94, 127.25, 127.19, 126.35, 123.41, 120.62, 119.98, 119.91, 111.1, 110.31, 109.95; HRMS(FAB) m/z calcd for C₃₆H₂₆BN₃(M⁺)511.2220, obsd.511.2219. Anal. Calcd for C₃₆H₂₆BN₃: C, 84.55; H, 5.12; B, 2.11; N, 8.22. Found: C, 84.15; H, 5.11; N, 8.12.

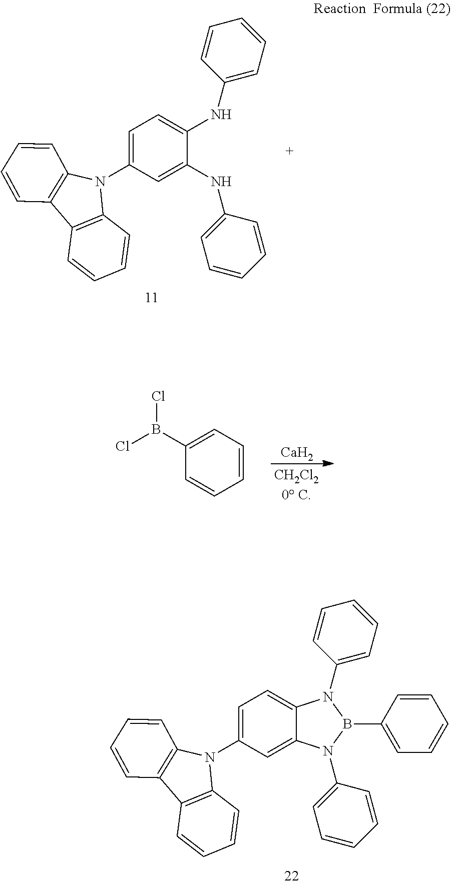

### EXAMPLE 23

### Synthesis of Chemical Formula (4)-Compound 23 (oCb)

Calcium hydride (0.17 g, 4.0 mmol) was provided in a 50 ml tri-neck bottle and two sets of dropping funnels were set in an inert atmosphere. The deoxygenated and dehydrated DCM (5 ml) was added into the reaction bottle. The 3-(9H-carbazol-9-yl)-N¹,N²-diphenylbenzene-1,2-diamine (compound 16, 0.34 g, 0.79 mmol) was added in one dropping funnel. The dichlorophenylborane (0.16 ml, 1.20 mmol) was added into the other dropping funnel. Each of the dropping funnels was added with 2.5 ml DCM and slowly dropped into the bottle under ice bath. One hour later, the mixture was warmed to room temperature and stirred for 10 hours. The mixture was filtered and the filtrate was extracted with aqueous potassium carbonate solution. The organic layer was dried with anhydrous MgSO₄ and concentrated under vacuum. The crude was washed by ether to obtain compound 23 (oCb, Chemical Formula (4), 0.30 g, yield: 73%) as a white solid. The foregoing reaction is as shown in the Reaction Formula (23).

Spectral data as follow: m.p.=224° C.; ¹H NMR (400 MHz, CD₂Cl₂): δ 7.82(d, J=7.8 Hz, 2H), 7.50-7.46(m, 2H), 7.41-7.38(m, 3H), 7.31(t, J=7.6 Hz, 2H), 7.24-7.04(m, 8H), 6.98-6.97(m, 4H), 6.50-6.43(m, 3H), 6.19(t, J=7.6 Hz, 2H); ¹³C NMR (100 MHz, CD₂Cl₂): δ 142.33, 141.00, 140.83, 138.75, 134.98, 134.55, 129.94, 129.06, 128.47, 127.63, 127.22, 127.09, 126.73, 125.91, 125.81, 123.37, 122.69, 121.52, 120.94, 120.11, 119.56, 111.17, 110.67; HRMS(FAB) m/z calcd for C₃₆H₂₆BN₃(M⁺)511.2220, obsd. 511.2221. Anal. Calcd for C₃₆H₂₆BN₃: C, 84.55; H, 5.12; B, 2.11; N, 8.22. Found: C, 84.43; H, 5.17; N, 8.30.

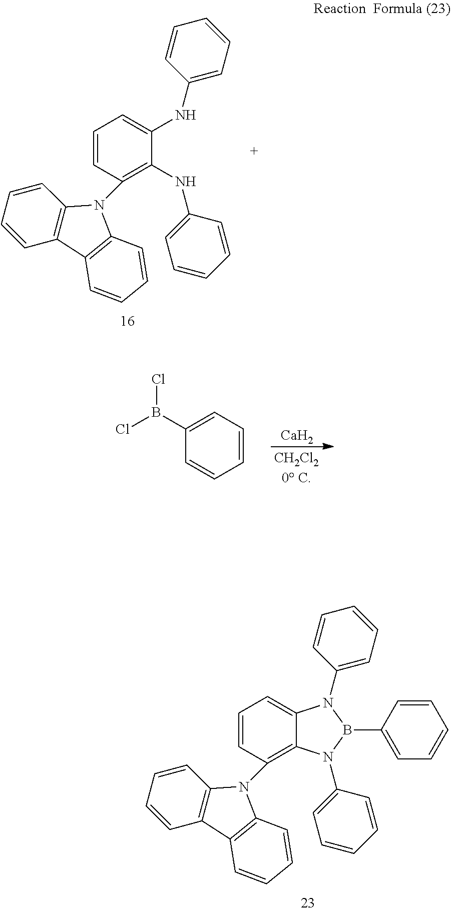

### EXAMPLE 24

### Synthesis of Chemical Formula (5)-Compound 24 (dCb)

Calcium hydride (0.30 g, 7.14 mmol) was provided in a 50 ml tri-neck bottle and two sets of dropping funnels were set in an inert atmosphere. The deoxygenated and dehydrated DCM (10 ml) was added into the reaction bottle. The 4,5-di(9H-carbazol-9-yl)-N¹,N²-diphenylbenzene-1,2-diamine (compound 13, 0.80 g, 1.36 mmol) was added in one dropping funnel. The dichlorophenylborane (0.25 ml, 1.94 mmol) was added into the other dropping funnel. Each of the dropping funnels was added with 5 ml DCM and slowly dropped into the bottle under ice bath. One hour later, the mixture was warmed to room temperature and stirred for 10 hours. The mixture was filtered and the filtrate was extracted with aqueous potassium carbonate solution. The organic layer was dried with anhydrous MgSO₄ and concentrated under vacuum. The crude was washed by ether to obtain compound 24 (dCb, Chemical Formula (5), 0.65 g, yield: 71%) as a white solid. The foregoing reaction is as shown in the Reaction Formula (24).

Spectral data as follow: ¹H NMR (400 MHz, DMSO-d₆): δ 7.89(d, J=7.6 Hz, 4H), 7.50-7.48(m, 4H), 7.44(t, J=7.5 Hz, 4H), 7.33-7.25(m, 9H), 7.21-7.17(m, 4H), 7.10(t, J=7.4 Hz, 4H), 7.02(t, J=7.4 Hz, 4H); ¹³C NMR (100 MHz, CD₂Cl₂): δ 141.43, 140.24, 139.17, 135.20, 130.16, 129.67, 128.13, 128.05, 127.52, 125.78, 123.43, 120.24, 119.92, 111.88, 110.62; HRMS(FAB) m/z calcd for C₄₈H₃₃BN₄(M⁺)676.2798, obsd. 676.2800. Anal. Calcd for C₄₈H₃₃BN₄: C, 85.21; H, 4.92; B, 1.60; N, 8.28. Found: C, 84.28; H, 4.96; N, 8.34.

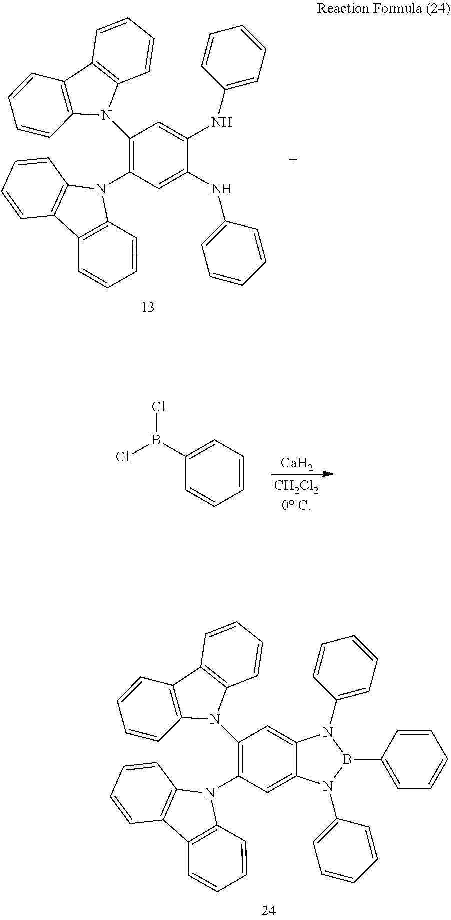

Evaluation methods for using benzodiazaborole derivative as the material of an organic light-emitting diode

The material of an organic light-emitting diode includes the compound which is mentioned above from Example 17 to Example 24 (compounds 17 to 24, i.e., Chemical Formulas (1) to (5), NS, mPh and mCb). The evaluation method for the material of an organic light-emitting diode is to discuss its thermal, photophysical and electrochemical properties, such as glass transition temperature (T_{g}), thermal decomposition temperature (T_{d}), melting point (Tₘ), absorption wavelength start value (λₒₙₛₑₜ^{abs}), maximum absorption wavelength (λₘₐₓ^{abs}), maximum emission peak wavelength (λₘₐₓ^{FL}) of normal temperature fluorescence, maximum emission peak wavelength of low temperature fluorescence (λₘₐₓ^{LTFL}) initial value of low temperature phosphorescence emission peak (λₒₙₛₑₜ^{LTPh}), quantum yield (Q.Y.), oxidation potential (E_{DPV}^{ox}), reduction potential (E_{DPV}^{re}), triplet energy level (E_{T}), highest occupied molecular orbital energy level (HOMO), lowest unoccupied molecular orbital energy level (LUMO), and energy gap (E_{g}).

The onset wavelength of absorbance (λₒₙₛₑₜ^{abs}), the wavelength of maximum absorbance (λₘₐₓ^{abs}), and the wavelength of maximum normal temperature fluorescence emission (λₘₐₓ^{FL}) are measured by using tetrahydrofuran as the solvent. The wavelength of maximum low-temperature fluorescence emission (λₘₐₓ^{LTFL}) and the onset wavelength of low temperature phosphorescence emission (λₒₙₛₑₜ^{LTPh}) are measured by using 2-methyltetrahydrofuran as the solvent. The quantum yield (Q.Y.) is measured by using toluene as the solvent and is calculated according to the following formula: Q.Y.=Q_{R}×(I/I_{R})×(OD_{R}/OD)×(n/n_{R})², where QR is the reference quantum yield (the quantum yield of the reference phenanthrene in ethanol is 0.125), I and I_{R} are the integrated peak areas of the fluorescence emission of the sample and the reference at the same excitation wavelength, respectively. The OD and OD_{R} are respectively the absorbance of the sample and the reference at the same wavelength, and n and n_{R} are the refractive indices of the solvent of the sample and the reference, respectively (see Dawson, W R; Windsor, M W, Fluorescence yields of aromatic compounds. The Journal of Physical Chemistry. 1968, 72 (9), 3251-3260.)

The melting point and the glass transition temperature are measured by differential scanning calorimeter (DSC), and the thermal decomposition temperature is measured by thermogravimetric analyzer (TGA), which is considered to be the basis of the stability for the fabrication and performance of unit.

The electrochemical properties (E_{DPV}^{ox}, E_{DPV}^{re}) of the compound are dissolved in dichloromethane and dimethylformamide, and measured by differential pulse voltammetry (DPV), respectively. The potential value is calibrated by the Ferrocene/Ferrocenium (Fc/Fc⁺) potential measured in the same condition. The highest occupied molecular orbital energy level (HOMO) is obtained by measuring the film state of the compound by atmospheric photoelectron spectroscopy. The energy gap (E_{g}) is derived from the onset wavelength of absorbance at room temperature. The lowest unoccupied molecular orbital energy level (LUMO) is the sum of HOMO and E_{g}. Understanding HOMO and LUMO of a compound can help to find a matched charge injection or transporting material, thereby improving the efficiency. In addition, the triplet energy level (E_{T}) of the compound, which is an important basis for whether it can be used as a host material, is calculated by the λₒₙₛₑₜ^{LTPh} measured at 0 K. The common guest emitter of the blue organic light-emitting diode is FIrpic (E_{T}=2.65 eV). Therefore, the E_{T} of host emitter used with FIrpic should be higher than 2.65 eV to avoid low luminous efficiency caused by reverse energy transfer.

The thermal properties of compounds 17 to 24 (Chemical Formula (1) to Chemical Formula (5), NS, mPh and mCb) are listed in the following Table 1.

TABLE 1

| Compound | M.W. | T_{g} (° C.) | Tₘ (° C.) | T_{d} (° C.)^{a} |
|---|---|---|---|---|
| NS | 346.16 | —* | 184 | 229 |
| mPh | 422.20 | 65 | 210 | 248 |
| Chemical Formula (1) | 472.21 | 80 | 224 | 287 |
| Chemical Formula (2) | 422.20 | 56 | 161 | 210 |
| Chemical Formula (3) | 472.21 | 72 | 196 | 282 |
| mCb | 511.22 | 104 | 291 | 307 |
| Chemical Formula (4) | 511.22 | 84 | 224 | 275 |
| Chemical Formula (5) | 676.28 | —* | 358^{b} | 374 |

^{a}indicates that the thermal decomposition temperature is accompanied by a weight loss of 5%.
^{b}indicates that the data are measured at National Taiwan University Valuable Instrument Center.
*indicates that it cannot be measured.

The optical properties of compounds 17 to 24 (Chemical Formula (1) to Chemical Formula (5), NS, mPh and mCb) are listed in the following Table 2.

TABLE 2

| | λₒₙₛₑₜ^{abs} | λₘₐₓ^{abs} | λₘₐₓFL | λₘₐₓ^{LTFL} | λₒₙₛₑₜ^{LTPh} | |
|---|---|---|---|---|---|---|
| Compound | (nm) | (nm) | (nm) | (nm) | (nm) | Q.Y. |
| NS | 315 | 295 | 366 | 342 | 367 | 0.62 |
| mPh | 334 | 308 | 356 | 350 | 424 | 0.99 |
| Chemical | 350 | 316 | 381 | 371 | 479 | 0.99 |
| Formula (1) | | | | | | |
| Chemical | 322 | 300 | 370 | 340 | 403 | 0.85 |
| Formula (2) | | | | | | |
| Chemical | 329 | 299 | 382 | 350 | 466 | 0.98 |
| Formula (3) | | | | | | |
| mCb | 351 | 293 | 364 | 354 | 399 | 0.71 |
| Chemical | 347 | 294 | 345 | 346 | 399 | 0.88 |
| Formula (4) | | | | | | |
| Chemical | 349 | 293 | 349 | 345 | 401 | 0.64 |
| Formula (5) | | | | | | |

The electrochemical properties of compounds 17 to 24 (Chemical Formula (1) to Chemical Formula (5), NS, mPh and mCb) are listed in the following Table 3.

TABLE 3

| | | | HOMO | E_{g} | LUMO | E_{T} |
|---|---|---|---|---|---|---|
| Compound | E_{DPV}^{ox}^{a} | E_{DPV}^{re}^{b} | (eV) | (eV)^{c} | (eV)^{d} | (eV)^{e} |
| NS | 0.678 | −3.089 | −6.03 | 3.88 | −2.15 | 3.38 |
| mPh | 0.574 | −2.918 | −5.84 | 3.67 | −2.17 | 2.93 |
| Chemical Formula | 0.492 | −2.744 | −5.71 | 3.55 | −2.16 | 2.59 |
| (1) | | | | | | |
| Chemical Formula | 0.607 | −3.039 | −5.88 | 3.81 | −2.07 | 3.08 |
| (2) | | | | | | |
| Chemical Formula | 0.602 | −2.796 | −5.90 | 3.76 | −2.14 | 2.66 |
| (3) | | | | | | |
| mCb | 0.467 | −2.999 | −5.65 | 3.50 | −2.15 | 3.11 |
| Chemical Formula | 0.612 | −3.134 | −5.92 | 3.56 | −2.36 | 3.11 |
| (4) | | | | | | |
| Chemical Formula | 0.508 | −3.035 | −5.74 | 3.56 | −2.18 | 3.09 |
| (5) | | | | | | |

^{a}indicates that the compound is dissolved in DCM.
^{b}indicates that the compound is dissolved dimethylformamide.
^{c}indicates the result is calculated by the formula E_{g} (eV) = 1240.8/λ_{(film)onset}^{abs}.
^{d}indicates the result is calculated by the formula LUMO = HOMO + E_{g}.
^{e}indicates the result is calculated by the formula E_{T} (eV) = 1240.8/λₒₙₛₑₜ^{LTPh}.

As shown in Tables 1 to 3, the Chemical Formulas (1) to (5) all have a high thermal decomposition temperature, and the thermal decomposition temperature of the Chemical Formula (5) is even higher than 300° C. The Chemical Formulas (1) to (5) have quite good thermal stability, especially the Chemical Formula (5). Presumably it is because the Chemical Formula (5) contains a rigid polyphenyl ring structure and shows a better thermal stability. Based on the above measurement results, the Chemical Formulas (1) to (5) have good thermal stability, high triplet energy level and have the potential to be the host material of the organic light-emitting diode.

The efficiency of Chemical Formula (5) which was used as the host material in the organic light-emitting diode.

The unit structure is ITO/TAPC(50 nm)/mCP(10 nm)/host:emitter(30 nm)/DPPS(40 or 45 nm)/LiF(0.7 nm)/Al(120 nm). The host material of the organic luminescent layer is based on the compound 17 and Chemical Formula (5). The host materials are mixed with the guest material at various ratio of emitter (FIrpic). Herein, compound 17 is used as the reference group, and the material of the first electrode layer of the organic light-emitting diode is ITO. The material of the second electrode layer is aluminum with the thickness of 120 nm. The material of the hole transport layer is TAPC with the thickness of 50 nm. The thickness of the organic luminescent layer is 30 nm. The material of the electron blocking layer is mCP (1,3-Bis(N-carbazolyl)benzene) with the thickness of 10 nm. The material of the electron transport layer is DPPS with the thickness of 40 or 45 nm. The material of electron injecting layer is LiF with the thickness of 0.7 nm. The above-mentioned layers are made by vapor deposition to form the organic light-emitting diodes of the embodiment, and the driving voltage (V), the turn-on voltage, the maximum luminance (Lₘₐₓ, cd/m²), the maximum current efficiency (CEₘₐₓ, cd/A), the maximum power efficiency (PEₘₐₓ, 1 m/W) and the maximum external quantum efficiency (EQEₘₐₓ, %) of the organic light-emitting diode are measured. The results are shown in Table 4.

TABLE 4

| | Driving | Turn-on | | | | |
|---|---|---|---|---|---|---|
| | voltage | voltage | Lₘₐₓ | CEₘₐₓ | PEₘₐₓ | EQEₘₐₓ |
| Unit | (V) | (V) | (cd/m²) | (cd/A) | (lm/W) | (%) |
| Compound | 8.19 | 7.22 | 3910 | 12.54 | 9.59 | — |
| 17-15%^{a} | | | @12 V | @4.5 V | @4 V | |
| Chemical | 6.69 | 5.50 | 11680 | 18.07 | 13.23 | 8.26 |
| Formula | | | @10.5 V | @5 V | @3.5 V | |
| (5)-18%^{a} | | | | | | |

^{a}indicates the doping concentration of FIrpic

The character of the organic light-emitting diodes, which utilize Chemical Formula (5) as the host material, shown in Table 4 not only have low driving voltages but also have the fine maximum current efficiency, maximum power efficiency and maximum external quantum efficiency. Accordingly, the host materials of the present disclosure have high transmission rate of electrons and electron holes, and are not necessarily to be operated under high driving voltage. As shown in the above Table 3, the host materials of the present disclosure have higher triplet energy level which is beneficial to reduce reverse energy transfer and to improve the luminous efficiency of the organic light-emitting diodes.

Comparison of the efficiency of Chemical Formula (5) and mCP which is used as electron blocking layer in organic light-emitting diodes.

The unit structure is ITO/TAPC(50 nm)/EBL(10 nm)/host: emitter(30 nm:6% Firpic)/DPPS(45 nm)/LiF(0.7 nm)/Al(120 nm). The host materials is the 9,9′-(2-(1-phenyl-1H-benzo[d]imidazol-2-yl)-1,3-phenylene)bis(9H-carbazole) and mixed with the guest material (FIrpic) at various ratio. Herein, the material of the first electrode layer of the organic light-emitting diode is ITO. The material of the second electrode layer is aluminum with the thickness of 120 nm. The material of the hole transport layer is TAPC with the thickness of 50 nm. The material of the electron blocking layer is Chemical Formula (5) or mCP with the thickness of 10 nm. The thickness of the organic luminescent layer is 30 nm. The material of the electron transport layer is DPPS with the thickness of 45 nm. The material of electron injecting layer is LiF with the thickness of 0.7 nm. The above-mentioned layers are made by vapor deposition to form the organic light-emitting diodes of the embodiment, and the efficiency items of the units are evaluated. The results are shown in Table 5.

TABLE 5

| | Driving | | | | |
|---|---|---|---|---|---|
| | voltage | Lₘₐₓ | CEₘₐₓ | PEₘₐₓ | EQEₘₐₓ |
| Unit | (V) | (cd/m²) | (cd/A) | (lm/W) | (%) |
| mCP | 7.96 | 15920@10 V | 56.91@4.0 V | 50.38@3.5 V | 26.99 |
| Chemical Formula | 7.86 | 20890@11.5 V | 51.66@5.0 V | 39.10@4.0 V | 25.35 |
| (5) | | | | | |

According to the results shown in Table 5, it is obviously known that the electron blocking layer made of Chemical Formula (5) has a lower driving voltage and a larger maximum luminance, which means that the compound of Chemical Formula (5) can be utilized as the electron blocking layer.

Comparison of the efficiency of Chemical Formula (5) and mCb which are used as hole-only devices (HOD) and hole transport layers in organic light-emitting diodes.

The theory of a hole transporting element (or electron transporting element) is that the designed element only allows holes (or electrons) to be injected while blocking the relative electrons (or holes) from the organic layer. Therefore, the recombination of charges does not occur in the organic layer and does not emit light. The mobility of holes or electrons is determined by the driving voltage and the current density of the unit. Theoretically, if the driving voltage is lower, the larger current density can obtain the larger mobility of holes or electrons.

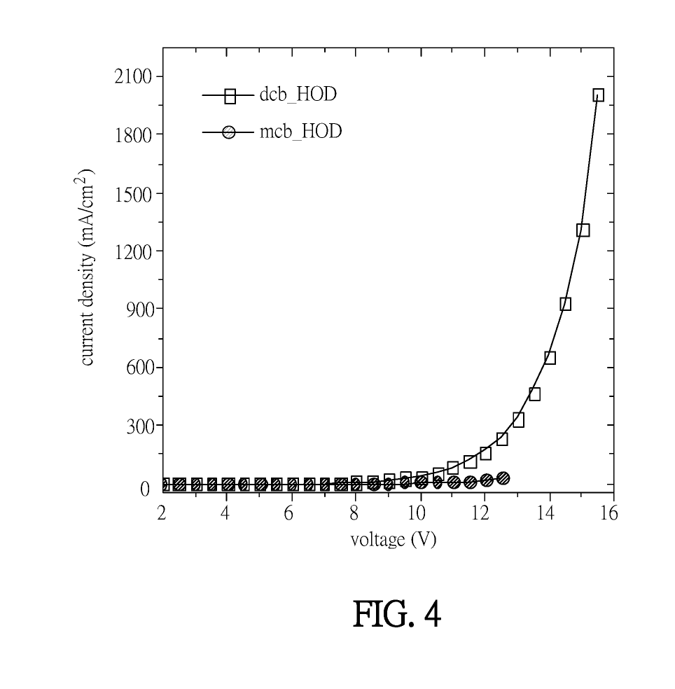

The structure of the hole transporting element is Al(50 nm)/MoO₃(10 nm)/mCP(10 nm)/Chemical Formula (5) or mCb (100 nm)/mCP(10 nm)/MoO₃(10 nm)/Al(100 nm). The material of the organic layer is based on Chemical Formula (5), and mCb is used as the reference material. The material of the first electrode layer of the hole transporting element is aluminum with the thickness of 50 nm, and the material of the second electrode layer is aluminum with the thickness of 100 nm. The material of the hole injecting layer is MoO₃ with the thickness of 10 nm. The material of the hole transport layer is mCP with the thickness of 10 nm. The organic layer is Chemical Formula (5) or mCb with the thickness of 100 nm. The above-mentioned layers are made by vapor deposition to form the hole transporting elements of the embodiment, and the current characteristics and charge injection benefits are evaluated. The results are shown in FIG. 4.

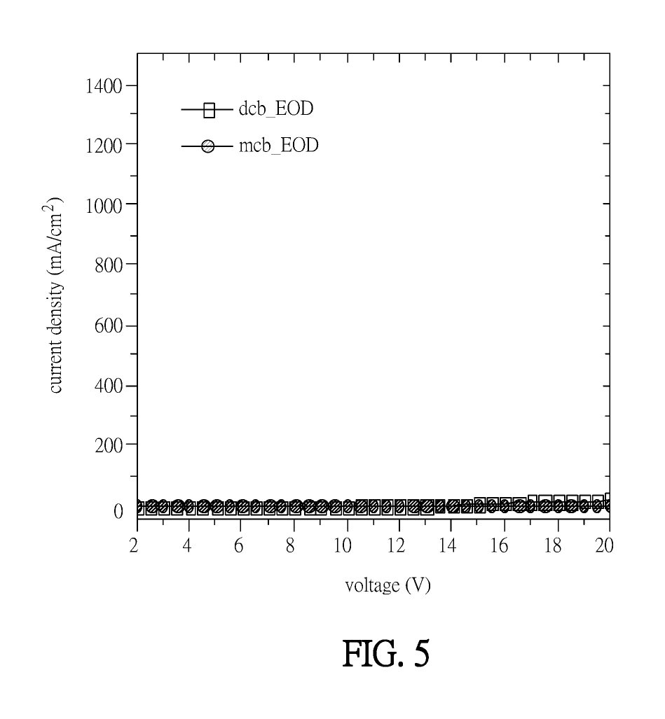

The structure of the electron transporting element is Al(50 nm)/LiF(1.5 nm)/DPPS(10 nm)/Chemical Formula (5) or mCb (100 nm)/DPPS(10 nm)/LiF(1.5 nm)/Al(100 nm). The material of the organic layer is based on Chemical Formula (5), and mCb is used as the reference material. The material of the first electrode layer of the electron transporting element is aluminum with the thickness of 50 nm, and the material of the second electrode layer is aluminum with the thickness of 100 nm. The material of the electron injecting layer is LiF with the thickness of 1.5 nm. The material of the electron transport layer is DPPS with the thickness of 10 nm. The organic layer is Chemical Formula (5) or mCb with the thickness of 100 nm. The above-mentioned layers are made by vapor deposition to form the electron transporting elements of the embodiment, and the current characteristics and charge injection benefits are evaluated. The results are shown in FIG. 5.

Please refer to FIGS. 4 and 5. FIG. 4 is a schematic graph showing the charge injection properties of the hole transporting element with the organic layer made of mCb or Chemical Formula (5), and FIG. 5 is a schematic graph showing the charge injection properties of the electron transporting element with the organic layer made of mCb or Chemical Formula (5). As shown in FIG. 4, the organic layer made of Chemical Formula (5) has a better current density than the organic layer made of mCb, which means the organic layer made of Chemical Formula (5) has better hole transporting ability. As shown in FIG. 5, the changes cannot be injected into the organic layer made of Chemical Formula (5) under the high voltage circumstance, and the charges in the organic layer made of Chemical Formula (5) is saturated. This property allows the organic layer made of Chemical Formula (5) to have the function of electronic blocking layer.

As mentioned above, in the benzodiazaborole derivatives and the organic light-emitting diodes by using the same according to the present disclosure, it utilizes 1,3,2-benzodiazaborole as a core structure, and different substituents are introduced to the ortho and/or meta positions of the benzo group. Thus, the benzodiazaborole derivatives of this disclosure can be used as the host material of the blue phosphorescent organic light-emitting diodes with high efficiency and good thermal stability. In addition, the benzodiazaborole derivatives of this disclosure can also be used as the electron blocking layer.

Although the disclosure has been described with reference to specific embodiments, this description is not meant to be construed in a limiting sense. Various modifications of the disclosed embodiments, as well as alternative embodiments, will be apparent to persons skilled in the art. It is, therefore, contemplated that the appended claims will cover all modifications that fall within the true scope of the disclosure.

What is claimed is:

1. A benzodiazaborole derivative, comprising a structure of the following General Formula (1), 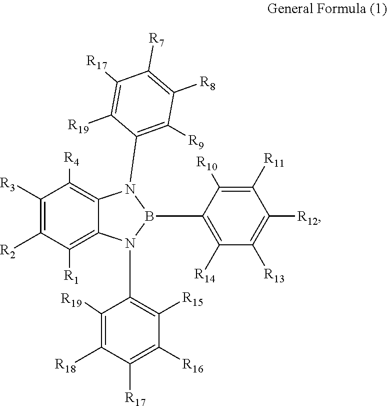
wherein R₁ is selected from the group consisting of hydrogen atom, General Formula (2), General Formula (3) and General Formula (4), R₂ is selected from the group consisting of hydrogen atom, General Formula (3) and General Formula (4), R₁ and R₂ are different and at least one of them is a hydrogen atom, R₃ is General Formula (4) when R₂ is General Formula (4), and R₃ is a hydrogen atom when R₂ is a hydrogen atom or General Formula (3); and 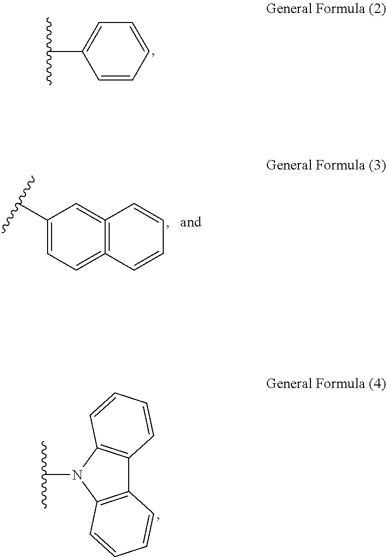
wherein R₄ to R₁₉ are independently selected from the group consisting of hydrogen atom, fluorine atom, cyano group, alkyl group, cycloalkyl group, alkoxy group, haloalkyl group, thioalkyl group, silyl group and alkenyl group.

2. The benzodiazaborole derivative according to claim 1, wherein the alkyl group is selected from the group consisting of a substituted or unsubstituted straight-chain C1˜C6 alkyl group, and a substituted or unsubstituted branched-chain C3˜C6 alkyl group, the cycloalkyl group is a substituted or unsubstituted C3˜C6 cycloalkyl group, the alkoxy group is selected from the group consisting of a substituted or unsubstituted straight-chain C1˜C6 alkoxy group, and a substituted or unsubstituted branched-chain C3˜C6 alkoxy group, the haloalkyl group is selected from the group consisting of a substituted or unsubstituted straight-chain C1˜C6 haloalkyl group, and a substituted or unsubstituted branched-chain C3˜C6 haloalkyl group, the thioalkyl group is selected from the group consisting of a substituted or unsubstituted straight-chain C1˜C6 thioalkyl group, and a substituted or unsubstituted branched-chain C3˜C6 thioalkyl group, the silyl group is selected from the group consisting of a substituted or unsubstituted straight-chain C1˜C6 silyl group, and a substituted or unsubstituted branched-chain C3˜C6 silyl group, the alkenyl group is selected from the group consisting of a substituted or unsubstituted straight-chain C2˜C6 alkenyl group, and a substituted or unsubstituted branched-chain C3˜C6 alkenyl group.

3. The benzodiazaborole derivative according to claim 1, comprising a structure of any of the following Chemical Formulas (1) to (5):

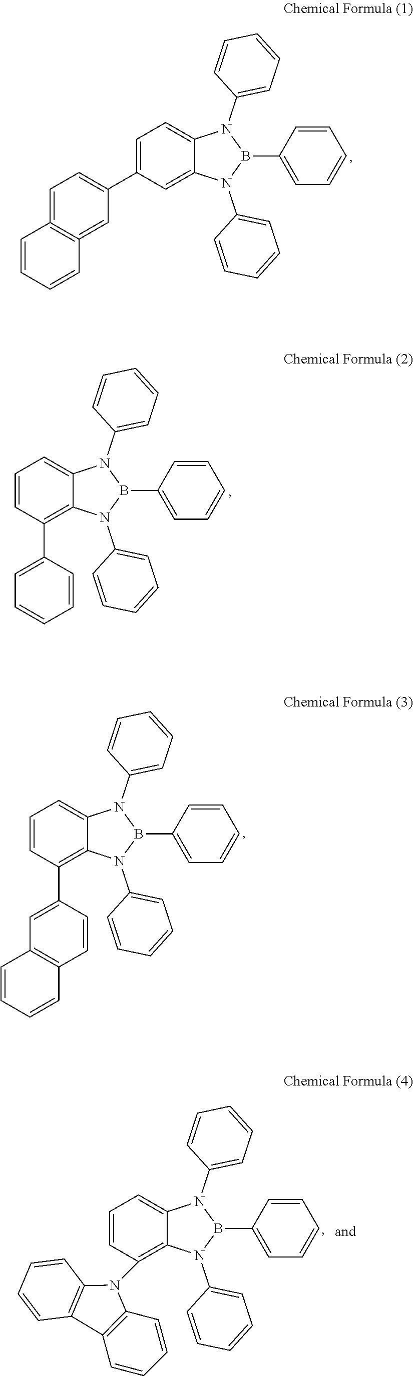

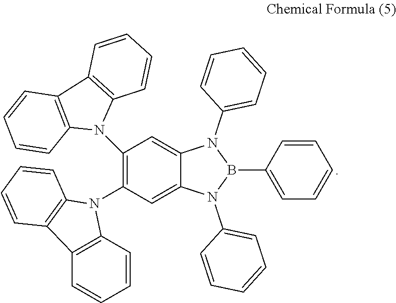 [SMILES: c1ccc(B2N(c3ccccc3)c3cc(-n4c5ccccc5c5ccccc54)c(-n4c5ccccc5c5ccccc54)cc3N2c2ccccc2)cc1]

4. An organic light-emitting diode, comprising:
a first electrode layer;
a second electrode layer; and
an organic luminescent unit disposed between the first electrode layer and the second electrode layer, wherein the organic luminescent unit comprises at least a benzodiazaborole derivative, and the benzodiazaborole derivative comprises a structure of the following General Formula (1), 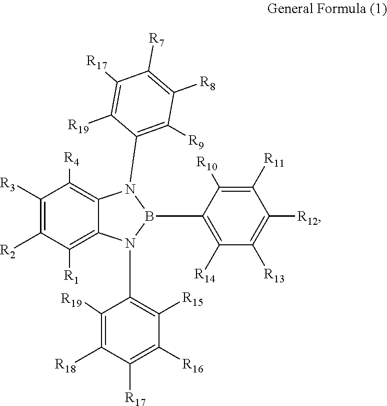
wherein R₁ is selected from the group consisting of hydrogen atom, General Formula (2), General Formula (3) and General Formula (4), R₂ is selected from the group consisting of hydrogen atom, General Formula (3) and General Formula (4), R₁ and R₂ are different and at least one of them is a hydrogen atom, R₃ is General Formula (4) when R₂ is General Formula (4), and R₃ is a hydrogen atom when R₂ is a hydrogen atom or General Formula (3); and 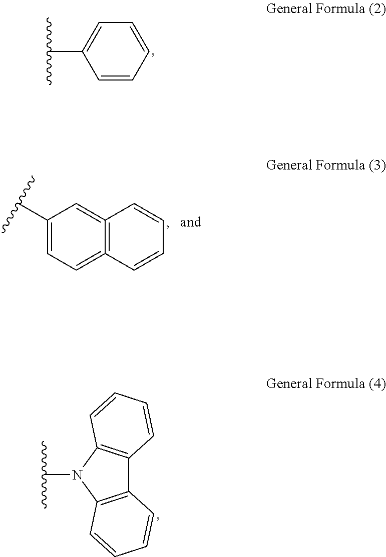
wherein R₄ to R₁₉ are independently selected from the group consisting of hydrogen atom, fluorine atom, cyano group, alkyl group, cycloalkyl group, alkoxy group, haloalkyl group, thioalkyl group, silyl group and alkenyl group.

5. The organic light-emitting diode according to claim 4, wherein the alkyl group is selected from the group consisting of a substituted or unsubstituted straight-chain C1˜C6 alkyl group, and a substituted or unsubstituted branched-chain C3˜C6 alkyl group, the cycloalkyl group is a substituted or unsubstituted C3˜C6 cycloalkyl group, the alkoxy group is selected from the group consisting of a substituted or unsubstituted straight-chain C1˜C6 alkoxy group, and a substituted or unsubstituted branched-chain C3˜C6 alkoxy group, the haloalkyl group is selected from the group consisting of a substituted or unsubstituted straight-chain C1˜C6 haloalkyl group, and a substituted or unsubstituted branched-chain C3˜C6 haloalkyl group, the thioalkyl group is selected from the group consisting of a substituted or unsubstituted straight-chain C1˜C6 thioalkyl group, and a substituted or unsubstituted branched-chain C3˜C6 thioalkyl group, the silyl group is selected from the group consisting of a substituted or unsubstituted straight-chain C1˜C6 silyl group, and a substituted or unsubstituted branched-chain C3˜C6 silyl group, the alkenyl group is selected from the group consisting of a substituted or unsubstituted straight-chain C2˜C6 alkenyl group, and a substituted or unsubstituted branched-chain C3˜C6 alkenyl group.

6. The organic light-emitting diode according to claim 4, wherein the benzodiazaborole derivative comprises a structure of any of the following Chemical Formulas (1) to (5):

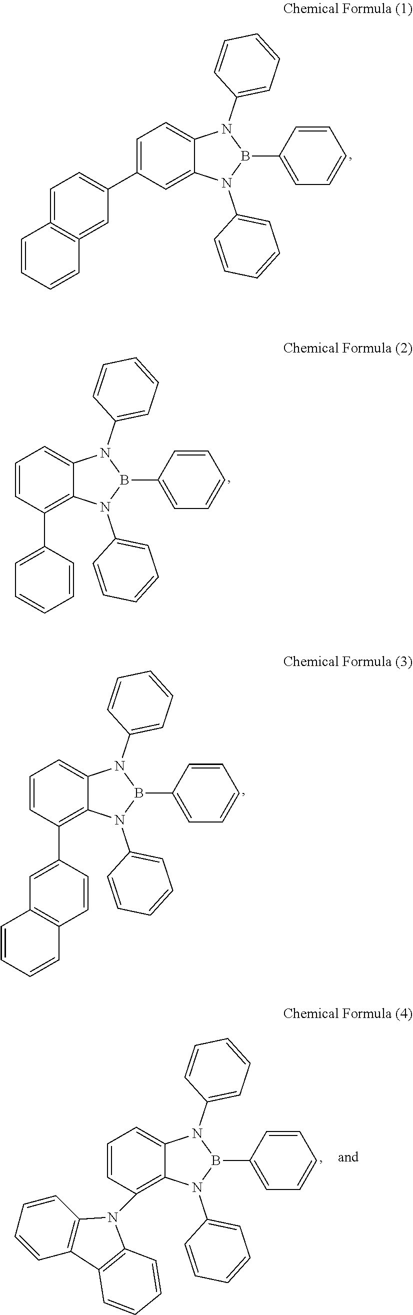

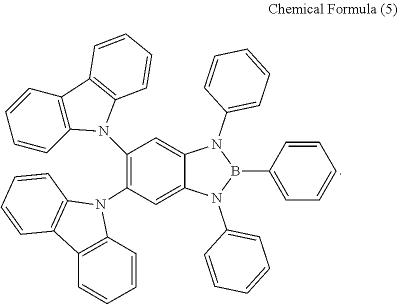 [SMILES: c1ccc(B2N(c3ccccc3)c3cc(-n4c5ccccc5c5ccccc54)c(-n4c5ccccc5c5ccccc54)cc3N2c2ccccc2)cc1]

7. The organic light-emitting diode of claim 4, wherein the organic luminescent unit comprises an organic luminescent layer.

8. The organic light-emitting diode of claim 7, wherein the organic luminescent unit further comprises a hole transport layer and an electron transport layer, and the organic luminescent layer is disposed between the hole transport layer and the electron transport layer.

9. The organic light-emitting diode of claim 7, wherein the organic luminescent unit further comprises a hole transport layer, an electron blocking layer, an electron transport layer and an electron injection layer, and the electron blocking layer, the organic luminescent layer and the electron transport layer are sequentially disposed between the hole transport layer and the electron injection layer.

10. The organic light-emitting diode of claim 7, wherein the organic luminescent layer comprises the benzodiazaborole derivative.

11. The organic light-emitting diode of claim 4, wherein the organic luminescent unit further comprises an electron blocking layer, and the electron blocking layer comprises the benzodiazaborole derivative.
